(19) United States
(12) Patent Application Publication
(10) Pub. No.: US 2023/0318261 A1
(43) Pub. Date: Oct. 5, 2023

(54) WAVELENGTH TUNABLE METASURFACE BASED EXTERNAL CAVITY LASER

(71) Applicant: PRESIDENT AND FELLOWS OF HARVARD COLLEGE, Cambridge, MA (US)

(72) Inventors: Michele TAMAGNONE, Cambridge, MA (US); Marco PICCARDO, Milano (IT); Dmitry KAZAKOV, Somerville, MA (US); Christina Maria SPÄGELE, Cambridge, MA (US); Federico CAPASSO, Cambridge, MA (US)

(73) Assignee: PRESIDENT AND FELLOWS OF HARVARD COLLEGE, Cambridge, MA (US)

(21) Appl. No.: 18/204,903

(22) Filed: Jun. 1, 2023

Related U.S. Application Data
(63) Continuation of application No. 17/923,886, filed on Nov. 7, 2022.
(60) Provisional application No. 63/022,270, filed on May 8, 2020.

(51) Int. Cl. H01S 5/14; B82Y 20/00; H01S 5/0687; G02B 26/08; G02B 1/00; H01S 5/028

(52) U.S. Cl. CPC H01S 5/141; B82Y 20/00; H01S 5/0687; G02B 26/0816; G02B 1/005; H01S 5/0283

(57) ABSTRACT

A laser device includes a gain medium including a facet. The laser device includes a metasurface including a plurality of supercells. The metasurface is disposed on a substrate and configured to reflect and focus a first portion of light from the facet back to the gain medium as a feedback beam. The metasurface can be configured to reflect a second portion of the light as an output beam at an angle that is nonzero relative to a direction of the feedback beam. The metasurface can be configured to transmit a second portion of the light as an output beam through the metasurface away from the facet. The emission wavelength of the laser device can be tuned by translating the metasurface. The output beam can be collimated towards a fixed direction while tuning the wavelength.

### CROSS-REFERENCE TO RELATED APPLICATIONS

The present application claims the benefit of and priority to U.S. Provisional Application No. 63/022,270, filed May 8, 2020, which is hereby incorporated by reference herein in its entirety.

### GOVERNMENT LICENSE RIGHTS

This invention was made with government support under 1807323 and 1541959 awarded by the National Science Foundation. The government has certain rights in the invention.

### TECHNICAL FIELD

The present application relates generally to tunable laser systems.

### BACKGROUND

External cavity lasers can include devices based on a gain medium and a set of optical elements which can lase under certain conditions.

### SUMMARY

The systems and methods of the present disclosure relate to tunable laser systems that can incorporate a metasurface. A metasurface can include an ensemble of subwavelength-spaced optical elements and can include a plurality of supercells. Wavelength, spectrum, and polarization tuning of external cavity lasers based on the metasurface as part of the cavity of a laser are provided. Tuning can be achieved by moving the metasurface with translation stages or electrically.

Dispersive reflective and transmissive metasurfaces, wavelength-tunable lasers systems incorporating these metasurfaces and methods to manufacture, arrange, control and align these systems are provided. Detailed system, methods, and configurations to tune the wavelength, suppress or induce laser mode hopping, control the polarization of the emitted light, and couple different lasers are also provided. The metasurface(s) used in these systems can create a wavelength-dependent and/or polarization dependent feedback which can be back-reflected to a component (e.g., laser, gain medium, chip, device, etc.), which can determine the lasing wavelength and/or polarization. In some embodiments, tunability can be achieved by mechanically translating and/or rotating the metasurface element or other components of the system or using electrically tunable metasurface elements. In some embodiments, both the feedback beam(s) and the output beam(s) created by the metasurface can be arbitrarily shaped and can include optical phase and polarization singularities to achieve precise phase and polarization control and multiwavelength operation. In some embodiments, the systems and methods of the present disclosure use a class of metasurfaces based on supercells. Metasurfaces based on supercells can allow the output beam of the laser and the feedback beam towards the component (e.g., laser, gain medium, chip, device, etc.) to be independently engineered.

At least one aspect of the present disclosure is directed to a laser device. The laser device includes a gain medium including a facet. The laser device includes a metasurface including a plurality of supercells. The metasurface is disposed on a substrate and may be configured to reflect and focus a first portion of light from the facet back to the gain medium as a feedback beam. The metasurface may be configured to reflect a second portion of the light as an output beam at an angle that is nonzero relative to a direction of the feedback beam.

Another aspect of the present disclosure is directed to a laser device. The laser device includes a gain medium including a facet. The laser device includes a metasurface including a plurality of supercells. The metasurface is disposed on a substrate and configured to reflect and focus a first portion of light from the facet back to the gain medium as a feedback beam. The metasurface can be configured to transmit a second portion of the light as an output beam through the metasurface away from the facet.

In some embodiments, the system can include one or more optical components (e.g., laser, gain medium, chip, device, etc.). Optical components can include semiconductor lasers, solid-state lasers, gas lasers, dye lasers, metal vapor lasers, unipolar lasers, or devices capable of amplifying light or electromagnetic radiation without any restriction on wavelength, size, and power. The gain medium or a portion of the gain medium can be coated with antireflection (AR) coatings (e.g., antireflective coatings) to match waves propagating along the gain medium with free space radiation. In some embodiments, the gain medium or a portion of the gain medium can be coated with high reflectivity (HR) coatings to prevent propagation of light in certain directions. In some embodiments, both antireflection and reflective coatings can be used.

In some embodiments, the system can include one or more metasurfaces. A metasurface can include an array of non-periodic or quasi-periodic elements placed on a surface (e.g., a flat surface, a curved surface, etc.) capable of locally altering the phase and amplitude of the light propagating through or reflected by the metasurface. In some embodiments, metasurfaces are defined on a substrate using various lithography techniques and either subtractive processes (e.g., etching) or additive processes (e.g., physical or chemical deposition). In some embodiments, elements are created with phase change materials and/or can be tuned (e.g., reconfigured) mechanically, electrically or optically.

In some embodiments, the relative and/or absolute position and tilting angles of these components in the reference frame of the device can be changed using translation stages (e.g., mechanical or electromechanical system such as motors, manual stages, piezoelectric stages and transducers). In some embodiments, the system formed by the gain medium and the metasurface can emit laser light (e.g., lases). The properties of the laser light can be controlled and/or tuned by changing the metasurface design or by moving the metasurface and/or gain medium with the translation and/or rotation stage. The metasurface can reflect a portion of the light emitted by the gain medium back to the gain medium itself. The portion of light reflected by the metasurface(s) back to the gain medium/media can be referred to as a feedback beam. In some embodiments, a portion of the light is allowed to escape the system as an output beam (e.g., another beam or set of beams, transmitted beam, etc.).

One or more additional optical elements (e.g., prisms, polarizers, wave plates, other metasurfaces, lenses, mirrors, beam splitters, filters, etc.) can be used between the gain medium and the metasurface or in the output beam to control (e.g., shape) the propagation of light. These elements are can be referred to as auxiliary optical elements. The auxiliary optical elements may not be the main active element of the optical filter.

The metasurface can act as an external cavity for the laser system. The gain medium together with the metasurface (and other auxiliary optical elements) can form a system in which light can propagate in closed loop(s) experiencing a unitary or more than unitary overall power gain, and act as a laser source. The ensemble of this closed loop and the components that form it can be referred to as the optical cavity (e.g., cavity). The existence of such loop may not prevent the existence/formation of the output beams.

In some embodiments, the metasurface can be used to control the shape, polarization and wavelength of both the feedback beam(s) and the output beam(s), and in some embodiments, in an independent manner. In some embodiments, the metasurface is based on supercells. In some embodiments, the translation of the metasurface allows for the continuous tuning of the wavelength of a collimated output beam without changing the propagation angle of the output beam itself. This condition can be referred to as fixed-angle collimated output.

In some embodiments, the system includes a fixed-angle collimated output, allowing for the independent control of a central wavelength and phase of the feedback beam. This condition can be used to achieve continuous wavelength tuning in external cavity systems. In some embodiments, the system can include one or more translation stages to achieve continuous wavelength tuning, and may not need rotation stages. In some embodiments, the system allows for arbitrary beam shapes, phase profiles, and polarization profiles for both the feedback and output beams, including the presence of phase and polarization singularities. In some embodiments, the emitted polarization of the laser system can be controlled. In some embodiments, alignment of the optical components can be simplified. In some embodiments, multiwavelength operation can be achieved and the time domain behavior of the emitted light can be controlled by controlling the mutual phase relation of the lasing wavelengths. Time domain engineering of optical signals can be achieved with metasurfaces.

Those skilled in the art will appreciate that the summary is illustrative only and is not intended to be in any way limiting. Other aspects, inventive features, and advantages of the devices and/or processes described herein, as defined solely by the claims, will become apparent in the detailed description set forth herein and taken in conjunction with the accompanying drawings.

### BRIEF DESCRIPTION OF THE DRAWINGS

The details of one or more implementations of the subject matter described in this specification are set forth in the accompanying drawings and the description below. Other features, aspects, and advantages of the subject matter will become apparent from the description, the drawings, and the claims.

FIG. 1 illustrates a schematic of a tunable external-cavity laser system, according to an embodiment.

FIG. 2 illustrates a schematic of a tunable external-cavity laser system, according to an embodiment.

FIG. 3 illustrates a schematic of a wavelength tuning principle of the metasurfaces, according to an embodiment.

FIG. 4 illustrates a schematic of light reflection, transmission, and diffraction by a supercell in a metasurface, according to an embodiment.

FIG. 5 illustrates a schematic of examples of design of the metasurface based on supercells for an external cavity laser, according to an embodiment.

FIG. 6 illustrates a schematic of a wavelength tunable metasurface based external cavity laser in oblique reflection configuration and divergent output, according to an embodiment.

FIG. 7A illustrates a schematic of a wavelength tunable metasurface based external cavity laser in oblique reflection configuration and fixed-angle collimated output, according to an embodiment.

FIG. 7B illustrates a collimated output beam projected on a screen, according to an embodiment.

FIG. 8 illustrates a schematic of a wavelength tunable metasurface based external cavity laser in oblique reflection configuration and fixed-angle collimated output including thermoelectric cooling element, according to an embodiment.

FIG. 9 illustrates a schematic of a cross section of a fabricated metasurface, according to an embodiment.

FIG. 10 illustrates a scanning electron microscopy image of a fabricated metasurface, according to an embodiment.

FIG. 11 illustrates a characterization of the fabricated wavelength tunable metasurface, according to an embodiment.

FIG. 12 illustrates a wavelength tunable metasurface based external cavity laser in a normal transmission configuration, according to an embodiment.

FIG. 13 illustrates a wavelength tunable metasurface based external cavity laser in an off-axis transmission configuration, according to an embodiment.

FIG. 14 illustrates an orbital angular momentum singularity in the feedback field, according to an embodiment.

FIG. 15 illustrates an electrically tunable metasurface external cavity laser, according to an embodiment.

Like reference numbers and designations in the various drawings indicate like elements.

### DETAILED DESCRIPTION

Following below are more detailed descriptions of various concepts related to, and implementations of, methods, apparatuses, and for tunable laser systems incorporating a metasurface. The various concepts introduced above and discussed in greater detail below may be implemented in any of a number of ways, as the described concepts are not limited to any particular manner of implementation. Examples of specific implementations and applications are provided primarily for illustrative purposes.

### I. Overview

External cavity lasers can include devices based on a gain medium (e.g. a diode laser gain chip) and a set of optical elements (e.g., an external cavity) which can provide feedback (e.g., reflect light back into the gain medium) to create an optical cavity which can lase (e.g., emit laser light) under certain conditions. The gain medium can be shaped as a waveguide, fiber or rod with two ends (e.g., facets). One or more of these ends can be coated with an antireflection (AR) coating that can prevent lasing when feedback is not available. The portion of the gain medium coated with the AR coating can have a reflectivity in the range of 10⁻⁴ to 10⁻⁵. The gain medium can emit a weak and incoherent electroluminescence radiation. Another end can have a high reflectivity (HR) coating or is uncoated/AR coated. In the uncoated/AR coated case, laser light can be emitted by this facet as well when the system operates with a proper feedback. The external cavity can contain filtering elements to control the wavelength and/or spectrum of the feedback. The system can lase at one particular wavelength which can be determined by the external cavity. During laser operation, the emitted light can be narrowband, with bandwidths in the range of MHz or kHz. This range may be several orders of magnitude smaller than the bandwidth of the gain medium so the emission can be monochromatic. For example, diode laser gain chips can have a bandwidth of a few THz. Furthermore, if the optical filter implemented in the external cavity is tunable, then the laser wavelength can be tuned across the whole bandwidth of the gain medium, while retaining its monochromaticity.

In some embodiments, a lens can be used to collimate the beam emerging from the AR facet of the gain medium. The beam can impinge on an optical grating which can be arranged so that only a narrow range of wavelengths is retroreflected (as the first diffraction order of the grating) and focused back on the facet, creating the feedback. Lasing can occur close to the central wavelength of the optical filter. Lasing can also be affected by the phase relation of the reflections at the two ends of the cavity. By rotating the grating, the central wavelength of this optical filter can be tuned, and the laser wavelength can be controlled. Part of the light can be reflected specularly by the grating, and this reflected light can be the output of the system. One consequence is that the rotation of the grating can change the direction of the output beam. Changing the direction of the output beam can be an undesirable effect because it can break the optical alignment with the rest of the setup that uses the laser light. In some embodiments, the light emerging from the other facet can be used. If the facet is also AR coated, then additional reflective elements can be used and aligned on that side. This can increase the complexity, cost and size of the system and make alignment more challenging. If the facet is partially reflective, the system may work but with reduced flexibility, since the facet reflectivity may not be able to be tuned dynamically which can limit the set of possible working conditions of the device.

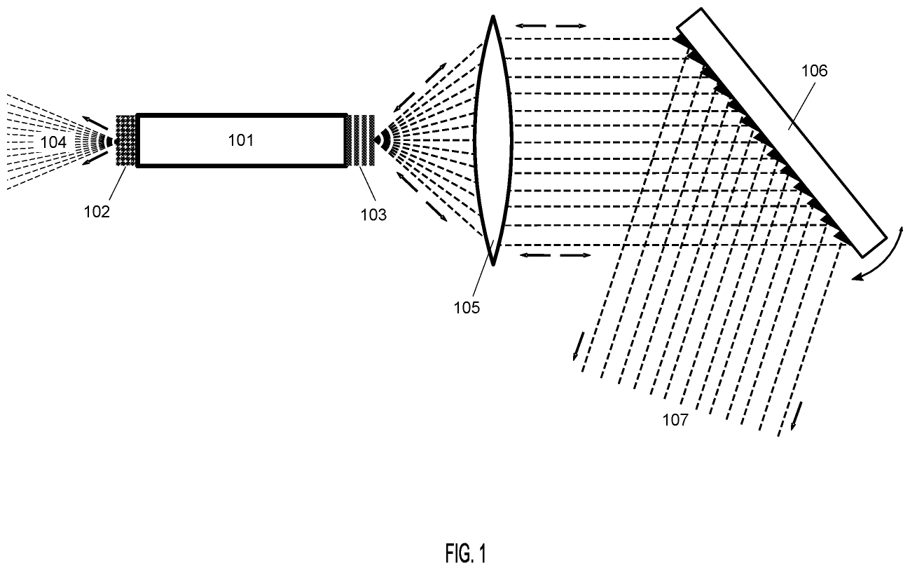

FIG. 1 illustrates a schematic of a tunable external-cavity laser system. The system can include a gain medium 101. The gain medium 101 can be coated on one side with an HR coating 102 and with an AR coating 103 on the other side. A low amount of residual light 104 can be transmitted through the HR coating 102 and can be used to monitor the laser power with a detector. For example, diode lasers with these coatings (e.g., HR coatings, AR coatings, etc.) can be used. A lens 105 can collimate the laser beam which can impinge on a diffraction grating 106. The diffraction grating 106 can reflect part of the collimated beam specularly to create the output beam 107 and diffract another part of power via the first diffraction order back to the lens. For a narrow window of the optical spectrum, the diffracted beam can be exactly retroreflected with the same angle of the collimated impinging beam. The lens 105 can focus the retroreflected portion (e.g., feedback) back to the gain medium 101. An optical cavity can be formed between the HR coating 102 and the diffraction grating 106. The optical cavity can include the gain medium 101 and the lens 105. If the gain of the gain medium 101 and the fraction of the power retroreflected by the cavity are sufficiently large, the cavity can lase at a wavelength determined by the position and tilt angle of the diffraction grating 106. Wavelength tuning can be achieved by rotating the diffraction grating 106 to tune the narrow spectral region retroreflected by the diffraction grating 106. Wavelength tuning can be achieved by translating the diffraction grating 106 to achieve a more accurate control of the feedback. Upon tuning, the output beam can rotate, which may be highly inconvenient for many applications. In some embodiments, the lens 105 and the diffraction grating 106 can be replaced by a metasurface.

To solve the issue of the output beam varying direction, in some embodiments, a rotating mirror is can be added to the system. The grating is arranged so that the first order of the beam can be sent to the mirror while the zeroth order (specular reflection) is the output beam. The mirror can be arranged so that one particular wavelength emerging from the grating is retroreflected to the grating, which, via first order diffraction, sends the light back to the lens and the facet. However, the grating can also specularly reflect part of this feedback, which exits the cavity and is lost. Because the grating does not rotate, the output beam can have a fixed direction, solving the shortcoming of the configuration described in FIG. 1. However, the power loss can limit the amount of power that can be generated in this configuration to about half of that of the configuration described in FIG. 1.

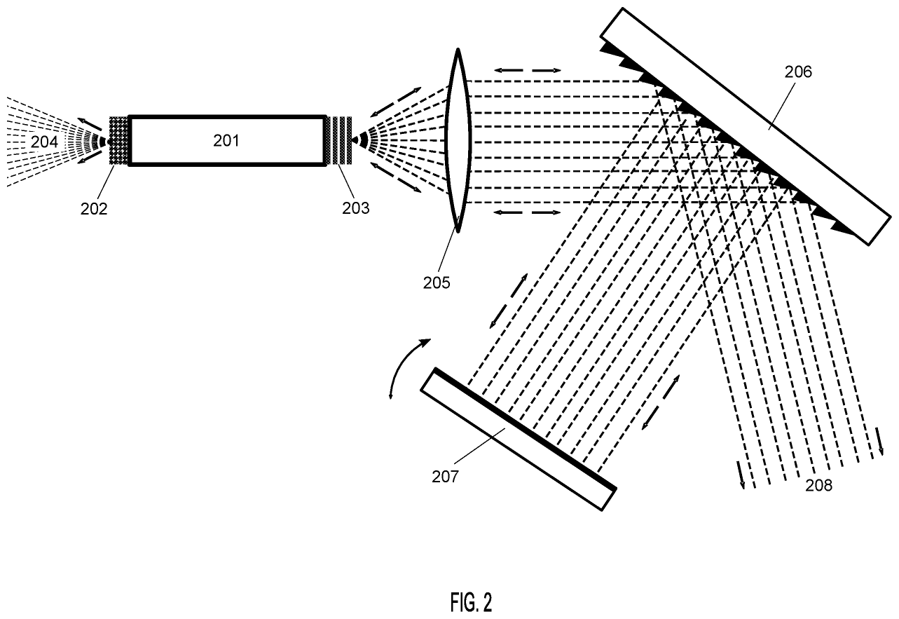

FIG. 2 illustrates a schematic of a tunable external-cavity laser system. The system includes a gain medium 201. The gain medium 201 can be coated on one side with HR coating 202 and with an AR coating 203 on the other side. A low amount of residual light 204 can be transmitted through the HR coating 202 and can be used to monitor the laser power with a detector. A lens 205 can collimate the laser beam which can impinge on a diffraction grating 206. The diffraction grating 206 can reflect part of the collimated beam specularly to create the output beam 208. The first order diffracted light can impinge on a mirror 207. For a narrow window of the optical spectrum, the light reflected by the mirror can be diffracted back to the lens and focused on the gain medium 201 as feedback. An optical cavity can be formed between the mirror 207 and the HR coating 202. The optical cavity can include the gain medium 201, the diffraction grating 206, and the lens 205. If the gain of the gain medium 201 and the fraction of the power retroreflected by the combination of diffraction grating 206 and mirror 207 are sufficiently large, the cavity can lase at a wavelength determined by the position and tilt angle of the diffraction grating 206. The diffraction grating 206 can have a fixed orientation, and the mirror 207 can be rotated to achieve wavelength tuning. Upon tuning, the output beam may not rotate, but the power can be reduced since only a portion of the light reflected by the mirror 207 is sent back to the laser by the diffraction grating 206. This additional loss can reduce the output power by roughly 50% for instance. In some embodiments, the lens 205, the diffraction grating 206, and the mirror 207 can be replaced by a metasurface.

The systems and methods of the present disclosure can solve issues related to the output beam varying direction, and limitations regarding the amount of power that can be generated by a tunable external-cavity laser. For example, the systems and methods of the present disclosure can realize a fixed-angle collimated output with a few as two components (e.g., one gain medium and one metasurface without auxiliary optical components). The systems and methods of the present disclosure can address alignment issues associated with a Littrow configuration of optical elements and can address optical losses associated with a Littman-Metcalf configuration of optical elements.

The systems and methods disclosed herein present a type of external cavity based on a metasurface. Metasurfaces can be formed by a set of diffractive and/or reflective elements arranged on a substrate (e.g., a transparent substrate, a reflective substrate, etc.). Metasurfaces can include optical elements that can implement various functions using an array of nanostructures on a substrate (e.g., flat substrate). The nanostructures can be engineered to impart locally different phases to an incident wavefront. The local phase can be chosen so that the phase delay is the same for every ray which is focused from the collimated beam to the focal spot. Constructive interference can be maximized in the focal spot. Metasurfaces can be used to shape the transmitted and/or reflected beam and for additional functionalities such as polarization optics and electro-optic beam steering. Metasurfaces can focus the light directly back to the facet of the gain medium. By moving the metasurface with respect to the facet, the laser wavelength can be tuned based on chromatic aberration of the metasurface focal spot. The systems and methods disclosed herein provide a device which can be wavelength tunable, compact, lightweight, easy to align, have high power output (e.g., less than 50% power loss), and have a collimated output beam which does not rotate upon wavelength tuning. The systems and methods of the present disclosure can provide a compact and flexible way to achieve optical feedback.

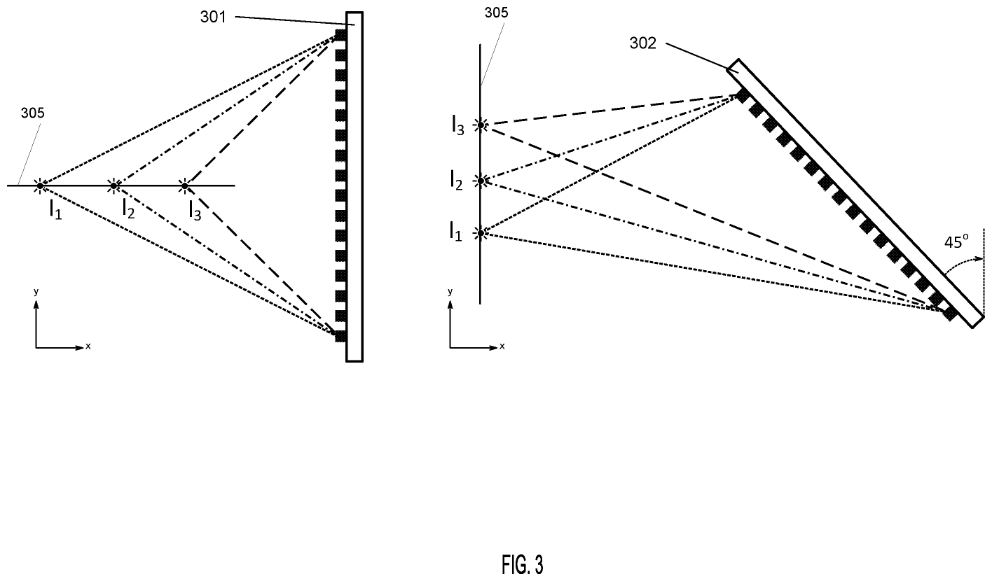

Dispersive reflective and transmissive metasurfaces, wavelength-tuneable lasers systems incorporating metasurfaces, and methods to manufacture, arrange, control and align these systems are provided. FIG. 3 illustrates a schematic of a wavelength tuning principle of the metasurfaces. The wavelength selection mechanism used in these metasurfaces can be based on chromatic dispersion of a focusing metasurface. A metasurface can include a regular or partially regular array of refractive and/or reflective elements on a substrate, which can shape light the metasurface transmits and/or reflects by imparting a linear optical response at each element. The linear optical response can be described locally by an amplitude and a phase. For local metasurface elements (e.g., with negligible coupling with neighboring elements) the amplitude may not exceed unity since the metasurfaces considered may not possess any gain media.

The optical response can depend on the geometry and optical property of the element itself. The optical response can consist of a phase delay and/or advance which can be locally imparted to light. The phase delay and/or advance can be changed across the metasurface to achieve beam shaping, and the function describing the phase dependence on the metasurface position can be referred to as phase profile. In some embodiments, phase and amplitude can be described together at the wavelength of interest by a complex amplitude can be defined with the phasor formalism as a complex number whose phase is the phase of the optical response and the amplitude is the amplitude of the of the optical response. Similarly to the phase profile, a complex amplitude profile can be defined to describe locally the response of the metasurface.

In some embodiments, a metalens is a metasurface that can focus a normally incident plane wave to a given point in space. This behavior can be achieved if the transmission and/or reflection phase of each of the discrete elements is selected to match the following design phase profile:

φ(r)=k₀(\sqrt{r²+f²}−f)+φ₀=k₀(\sqrt{x²+y²+f²}−f)+φ₀ (1)

where φ is the phase profile as function of the distance r=\sqrt{x²+y²} of the element from the center of the metalens, k₀=2π/λ is the wavevector of light in free space, λ is the wavelength of light, f is the focal length of the metalens and φ₀ is a constant arbitrary phase factor which may not affect the performance of the metalens. The behavior of the metalens can be explained locally in terms of ray optics considering that the wavevector emerging from the metasurface can be deflected by an amount equal to the gradient Δφ of the phase profile on the metasurface. The phase profile given in Equation 1 can provide the correct gradient to ensure that light is deflected towards the focal spot of the metasurface at each position. Light can be focused from one point back to itself, which can be achieved by metasurfaces operating in reflection doubling the wavevector deflection and hence doubling the phase profile:

φ(r)=2k₀(\sqrt{r²+f²}−f)+φ₀=2k₀(\sqrt{x²+y²+f²}−f)+φ₀ (2)

A metalens can focus a light beam propagating through the metalens in a diffraction limited focal spot. A metalens can be intrinsically dispersive.

A metasurface focusing light from a point source back to the source itself can be referred to as confocal metamirror or metamirror. The point for which this property hold can be called a feedback point. The metamirror can focus light back to the source only when the source is at (or sufficiently close to) the feedback point. If the source wavelength is changed by a small amount, within a first order approximation, the feedback point of the metamirror can move in space. This effect can be due to the chromatic aberration of the focal spot of metasurfaces. The aberration can follow different behaviors accordingly to the metasurface type. FIG. 3 shows two examples for normal metamirrors 301 and off-axis metamirrors 302 at 45° angle. In the normal metamirrors 301 case, the feedback point can move on a path along the metasurface axis, along the x-direction. In the off-axis metamirrors 302 at 45° angle case, the path can be at an angle with respect to the metasurface, along the y-axis. If a light source is placed on the path of the feedback point, it can experience optical feedback for a very narrow range of wavelength. This filtering effect can be used for wavelength selection in the devices disclosed here. Because the wavelength discrimination can be stronger in off-axis metasurfaces, these metasurfaces can be used for the devices disclosed here. The path is locally straight but can be curved for large changes in the wavelength (e.g., wavelength variation of 10%). In some embodiments the shape of the path can be designed by designing the metasurface. For example, the metasurface can be designed such that the path is a straight path for wide ranges of wavelengths (e.g., wavelength variation of 10%).

Reflective metasurfaces can be designed at the central design wavelength to reflect and refocus light originating from a source (e.g. a point source) back to the source itself. At the design wavelength, this behavior can be observed when the source is placed in one specific position. This can be referred to as the feedback point. Due to chromatic aberration of the metasurfaces, a very narrow wavelength range around the design wavelength can be focused back on the facet, achieving a wavelength filtered feedback. At other wavelengths, the same behavior can occur for a different metasurface feedback point in space. The position of the metasurface feedback point as a function of the wavelength can depend on the metasurface design. FIG. 3 illustrates the position of the metasurface feedback point as a function of the wavelength for three wavelengths λ₁<λ₂<λ₃ and two different choices of metasurface configurations: normal (e.g., normal metamirrors 301) and oblique incidence (off-axis metamirrors 302). The position of the metasurface feedback point can shift along the x-axis in the first case (normal metamirrors 301) and along the y-axis in the second case (off-axis metamirrors 302).

To implement the desired phase profile, a regular lattice of cells (e.g., square or rectangular) can be defined such that one metasurface element is found at each cell of the lattice. The lattice periodicity can be chosen to be subwavelength so that no grating orders other than the zeroth exist. A collection of elements (e.g., dielectric pillars) can be analytically or numerically simulated with periodic boundary conditions as a function of several parameters (e.g., size) of the element to evaluate the complex transmission and/or reflection phase of a perfectly periodic arrangement of these elements. An example of numerical method suitable for this simulation is rigorous coupled wave analysis (RCWA).

The simulation can be repeated for each choice of parameters and each simulation can add an entry of the metasurface library. The library can include a table where each entry relates the chosen pillar geometry and parameters to the achieved transmission and/or reflection phases and transmissivity. Phase and transmissivity can be combined in a single complex number. The metasurface may also affect the polarization of the incident light. The metasurface library can record the complex Jones matrix in transmission and reflection for each choice of geometry and parameters. The Jones matrix can describe the polarization behavior of the element. The phase profile can be implemented by choosing locally the metasurface element that can impart the desired local phase to the incident light. In some embodiments, the polarization can be considered.

This approach, which can be referred to as a single cell metasurface approach, can include the assumption that the coupling between cells is negligible, so that the choice of the element depends only on the phase at that position. For metasurfaces using normal incidence, the single cell metasurface approach can be useful. For off-axis metasurfaces, the size of the metasurface elements can be locally enforced to be a submultiple of the periodicity of the phase profile on the metasurface. Each cluster of elements can be a supercell, which can be optimized to take into account the coupling between adjacent elements. This approach can locally approximate a metasurface as a metagrating. A metagrating can include a grating formed by repeating several supercells in a periodic arrangement. Each supercell can be rigorously simulated with periodic boundary conditions since it is surrounded by identical elements.

A generalization of this approach is disclosed here, where the supercell is directly parametrized and simulated and used as the basic element of a metasurface that can implement different beam patterns in different directions (e.g., different grating orders). The geometry of the supercell can be arbitrary, as opposed to a sequence of predetermined cells. Because the primitive element of this type of metasurface can be a supercell instead of a single subwavelength cell, this class of metasurfaces can be referred to as a metasurface based on supercells. The metasurface based on supercells library can created similarly to the single cell metasurface by parametrizing the supercell and simulating it with periodic boundary conditions. The difference is that the results in each entry of the library can include the Jones matrices for each of the diffraction orders of the supercell. If the polarization of the incident light is known, the library can, alternatively, contain the Jones vectors of each of the diffractive orders. Different patterns can be implemented independently in each order by choosing, at each site of the lattice, the supercell element in the library that more closely implements simultaneously the phase in all the orders. The approach can be extended also to partially reflective metasurfaces based on supercells which can implement one phase profile in reflection and another one in transmission.

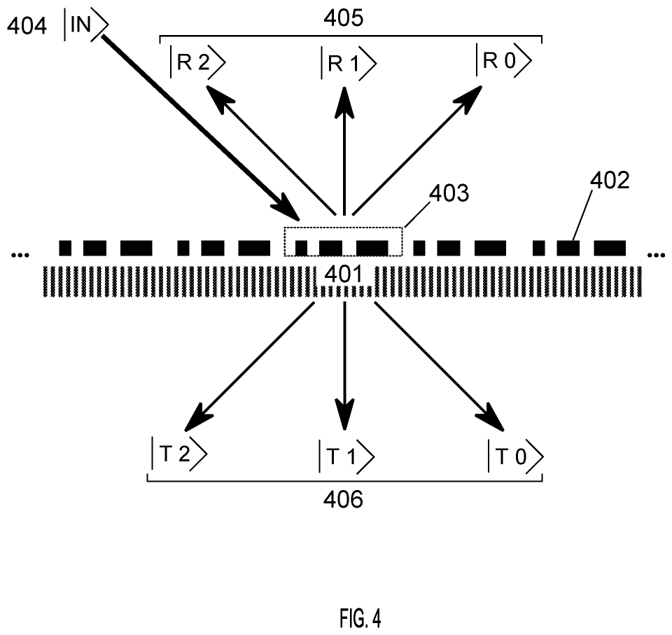

FIG. 4 illustrates a schematic of light reflection, transmission, and diffraction by a supercell in a metasurface. The substrate 401 can be flat. The substrate 401 can be fully reflective. The substrate 401 can be partially transparent and partially reflective. The metasurface can include elements 402 (e.g., metasurface elements). The elements 402 can be fabricated on top of the substrate 401. FIG. 4 depicts the local behavior of a single supercell 403 in a periodic boundary condition (e.g., assuming that the supercell is surrounded by identical copies tiling a regular lattice to form a metagrating). The actual metasurface based on supercells can include a generalization of this metagrating, since the adjacent supercells may be only approximately equal, and the lattice may be locally distorted, to implement the beam patterns, or a combination of both strategies. For example, the lattice can be a curvilinear lattice. The supercell can be designed with a specific input beam 404 locally approximated as a plane wave with a specific angle and polarization. This assumption can be valid if the metasurface based on supercells is sufficiently far from the source (e.g., an amount equal to the square of the lateral size of the facet divided by the minimum operation wavelength of the system). The supercells can reflect, transmit, and diffract the input beam in several output beams 405, 406 according to the supercell size. Changes in the supercell parameters can affect the phase, the polarization, and the intensity of all these diffracted beams (e.g., output states) simultaneously. Therefore, a library can be created which allows independent control of the beam pattern along each of these directions. Each output state can be described by its corresponding Jones vector, represented in bra-ket notation. If the polarization of incident light is not known, each of the orders can be more generally represented as a Jones matrix operator.

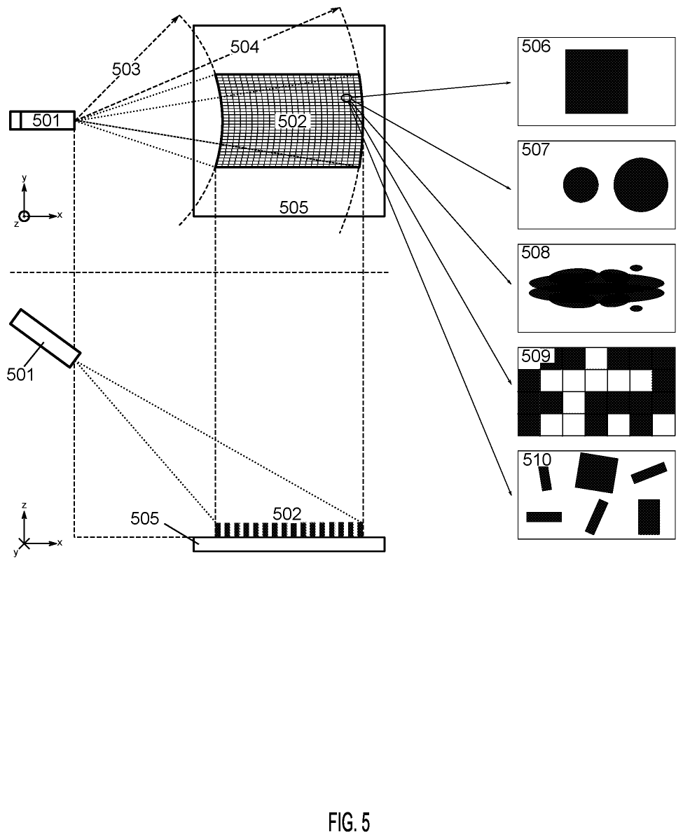

This generalization can be compatible with distorting the lattice of the metasurface based on supercells to impart an additional phase factor. The example shown in FIG. 5 illustrates a metasurface based on supercells where the supercell elements lie on a lattice which is not perfectly periodic in two dimensions, with the columns of the lattice having a circular geometry. A coordinate system can be described by two continuous functions a(x, y) and b(x, y) defined in such a way that lattice points (e.g., positions at which the supercells are located) correspond to values of x and y such that a and b are integer numbers. The supercells can be indexed with integers (nₐ,n_{b}) such that nₐ=a(x, y) and n_{b}=b(x, y). The complex amplitude profile in reflection implemented for one specific reflection or diffraction order of this metasurface based on supercells can be given by:

R_{N}_{ₐ}_{,N}_{_{b}}(x,y)=|C_{N}_{ₐ}_{,N}_{_{b}}(nₐ,n_{b}))exp(2πNₐa(x,y)+2πiN_{b}b(x,y)) (3)

where Nₐ, N_{b} are the indexes of the considered order, nₐ and n_{b} are the indexes of the supercell found at position (x, y), and |C_{N}_{ₐ}_{,N}_{_{b}}(nₐ, n_{b})) is the reflection coefficient (complex amplitude) of that cell for the considered order. For a single cell metasurface, Nₐ, N_{b}=0 so that the exponential is just a factor of 1. The cell can be to be chosen to implement the reflection phase and amplitude in that position. The same argument can hold for the case of transmission for transparent metasurfaces.

Metamirrors and metasurfaces based on supercells may be referred generically as metasurfaces. The example shown in FIG. 5 illustrates a light source and a metasurface based on supercells 502 designed in such a way that part of the light is focused back on the light source as a feedback beam and part is reflected specularly as the output beam. This metasurface based on supercells 502 can act as a beam splitter, splitting the incident light in two beams and performs simultaneously as a metamirror for the first beam and as mirror for the second. The complex amplitude coefficients (which generalize the beam splitting ratio) of these two beams can be C₁ and C₀ respectively.

Using Equation 3, this functionality can require:

R₀(x,y)=C₀;R₁(x,y)=R₀φ(r)=C₁ exp(2ik₀(\sqrt{x²+y²+f²}−f)) (4)

Assigning the feedback beam to the first order and the output beam to the zeroth order, the functionality can be implemented choosing the coordinate system:

$$a ( x , y ) = \frac{2}{λ} ( \sqrt{{x}^{2} + {y}^{2} + {f}^{2}} - f ) \\ b ( x , y ) = \frac{y}{h} \qquad ( 5 )$$

where h is the height of the metasurface supercells in FIG. 5. The design phase for each order can be:

R_{N}_{ₐ}_{=0,N}_{_{b}}₌₀(x,y)=C₀;R_{N}_{ₐ}_{=1,N}_{_{b}}₌₀(x,y)=C₁ exp(2ik₀(\sqrt{x²+y²+f²}−f)) (6)

which can match the phase profile. The split ratio can be determined by the supercell geometry and parameters and can be controlled by choosing or optimizing the appropriate supercell from the library.

FIG. 5 illustrates several examples of supercell geometries. The elements can include pillars fabricated on top of a substrate 505 (e.g., flat substrate, reflective substrate, flat and reflective substrate). The top view of example of possible unit cells 506-510 are also shown. The example of prototype disclosed below can use a single pillar per supercell, although multiple pillars with arbitrary geometries can be used as well. Free form supercells can be optimized with inverse design methods as well, especially for more advanced functionalities. For polarization functionalities, a relevant parameter can include the rotation of some of the pillars embedded in the supercell.

FIG. 5 illustrates a schematic of examples of design of the metasurface based on supercells for an external cavity laser. The gain medium 501 can face the metasurface based on supercells 502 with its AR coated side. The supercells can be arranged in a lattice chosen to achieve the focusing of the feedback beam back on the AR coated side of the gain medium 501. In this example, all cells can have the same size along the y-axis and can be distributed in regular rows. However, the position and size along the x-axis can be variable to implement the phase profile. The columns can include circular shapes with radiuses between r_{MAX} 503 and r_{MIN} 504 selected to maximize the coverage of the illuminated area. The substrate 505 can be flat. The geometry of the supercell can be chosen in many different ways. The unit cells can include a single geometric element. A single geometrical element 506 can be used. Alternatively, multiple elements 507 can be used, in both cases without restriction on the shape. Parameters such as position of the elements, width, length, and height, as well as additional geometrical values, can be used to achieve different diffraction output states. Moreover, arbitrary shapes 508 or pixelated patterns 509 can be generated with inverse design or other forms of optimization. The rotation of elements 510 can also be used as parameter, especially to implement polarization functions.

The determination of the complex coefficients Cᵢ (or in the most general case of the Jones matrices Jᵢ) for each order i can be achieved by numerically simulating each supercell with periodic boundary conditions. In addition, the beam shape can be engineered along each order by using different supercells at each lattice positions, so that the complex coefficient or Jones matrices can have a slow variation on the metasurface. Then, the beam shape can be determined via Fresnel diffraction as for a single cell metasurface, with the difference that different profiles can be achieved for each order.

### II. Examples of Wavelength Tunable Metasurface Based External Cavity Lasers in a Reflection Configuration Based on Translation Stages

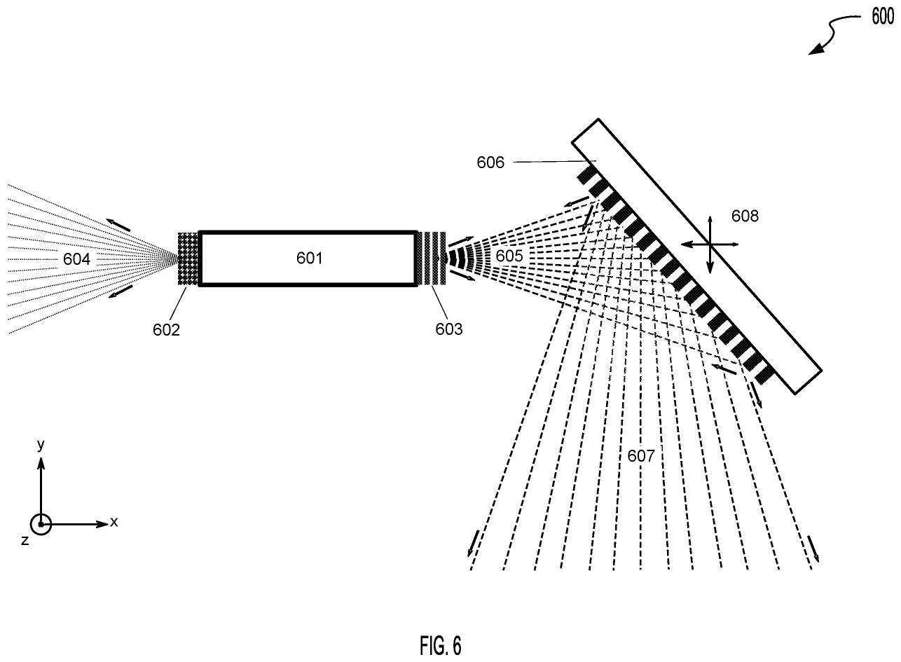

This section discloses examples of wavelength tunable metasurface based external cavity lasers in a reflection configuration based on translation stages (e.g., translational stages). FIG. 6 illustrates an example of a metasurface based on supercells used in an oblique (off-axis) configuration, with the feedback and output beam obtained using the profiles obtained in Equation 6. FIG. 6 illustrates a schematic of a wavelength tunable metasurface based external cavity laser in oblique reflection configuration and divergent output. This example can include a gain medium 601 with one HR coated facet (e.g., facet 602) and an AR coated facet (e.g., facet 603). A low amount of residual light 604 can be transmitted through the HR coating and can be used to monitor the laser power with a detector. If the facet is subwavelength, as in some laser diodes, then a metasurface based on supercells 502 (e.g., metasurface 606) can be designed assuming that the light source is a point, to reflect the light back to the point of origin. If the facet is larger, then the light 605 emitted by the facet might have a more complex pattern. In that case, the phase profile on the first order can be engineered to match the beam profile, ensuring that the feedback beam is the complex conjugate of the beam emitted by the facet. This can ensure that the feedback will couple completely to the facet. The output beam 607 can be is a specular (zeroth order) reflection of the light emitted by the facet, and hence it can be divergent. The light 605 emerging from the AR coated end of the gain medium 601 can impinge on the metasurface 606 which focuses part of the light directly back to the AR coated laser and specularly reflects the rest of the light in the output beam 607. The cavity can be created between the metasurface 606 and the HR coating, and includes the gain medium 601. The output light can be divergent. Wavelength tuning can be achieved by changing the position of the metasurface 606 with translation stages 608.

Tuning can be performed using mechanical stages to change the relative position of the metasurface based on supercells and the gain medium. Two tuning mechanisms can exist and can be used in the system to tune the emitted light. The first mechanism can include coarse tuning using the chromatic aberration of the metasurface based on supercells, implemented by moving, for example, the metasurface based on supercells along the y-axis. The portion of light retroreflected by the metasurface based on supercells and coupling back to the laser can be narrowband and the central wavelength can depend on the relative position along the y-axis. This filter can limit the range of wavelengths that can be emitted. However, more than one longitudinal cavity mode can lase, which can mean that more than one wavelength can lase at the same time, or mode hopping phenomena might occur. This can be due to the fact that the optical cavity delimited by the HR coating and the metasurface based on supercells acts as a Fabry-Perot resonator, and more than one resonance might fall in the range of the filter. To select one specific wavelength, a second fine tuning mechanism can be used. Fine tuning can be achieved by changing the relative position of the metasurface based on supercells and the gain medium along the x-axis by fractions of the wavelength. This translation may not affect the coarse filtering, but can change the position of the Fabry-Perot resonances so that it is possible to align one resonance to the central wavelength of the coarse wavelength filtering implemented by the metasurface based on supercells. It is possible to use both mechanisms at the same time to tune both the Fabry-Perot cavity and the filter to a given wavelength, which can allow for continuous wavelength tuning. Both tuning mechanisms can be implemented with translation stages. Residual light emitted by the HR coated facet can be used to monitor the laser power with a photodetector. In some embodiments, the system is compact, continuously tunable and allows for the maximum power extraction from the gain medium. Metasurfaces based on supercells can act as a splitter and can be designed with very low optical losses and with complete flexibility in terms of the splitting ratio.

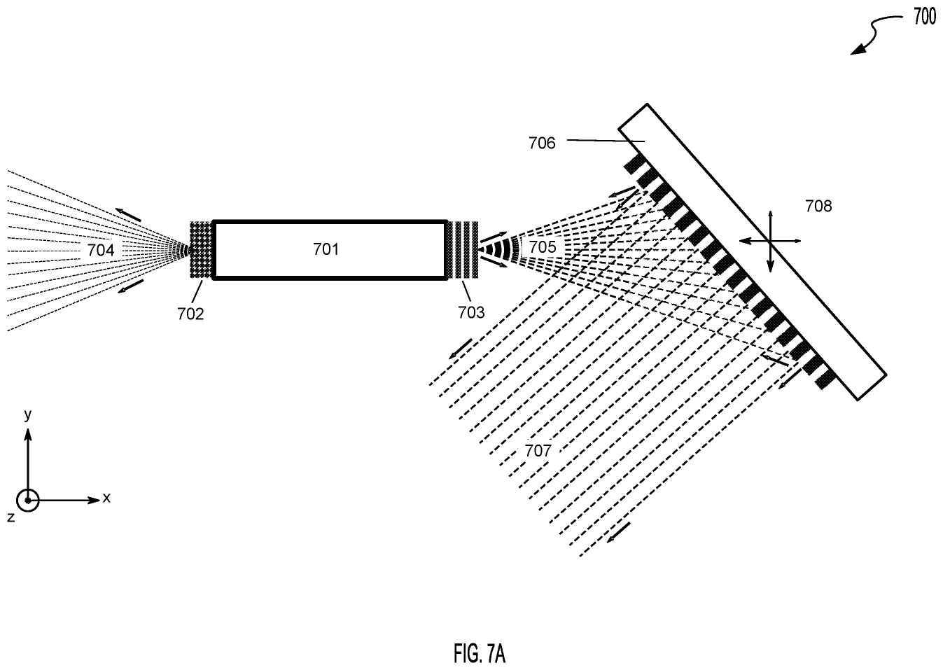

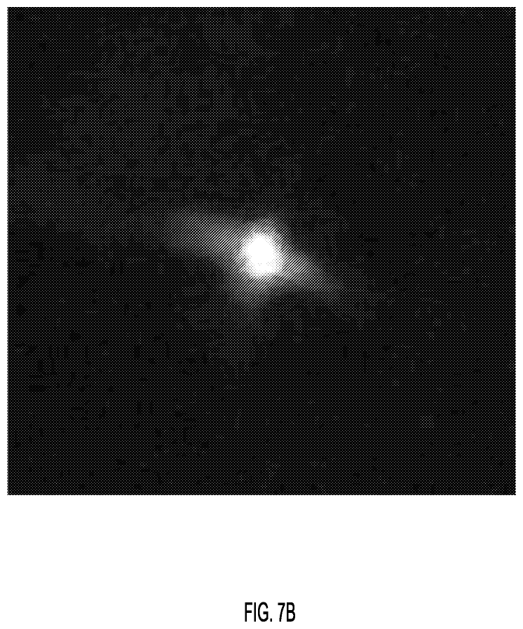

FIG. 7A shows a configuration which allows for an output beam that is collimated and does not change direction upon reconfiguration. The system can preserve the capability of extracting all the available power from the gain medium. In this configuration, the feedback beam can be generated as the second diffraction order of the metasurface based on supercells, so that:

$$a ( x , y ) = \frac{1}{λ} ( \sqrt{{x}^{2} + {y}^{2} + {f}^{2}} - f ) \\ b ( x , y ) = \frac{y}{h} \qquad ( 7 )$$

The function a(x, y) is divided by two to compensate the face that the second diffraction order is used instead of the first. The coefficients for the beam retroreflected to the laser is referred to as C₂.

For this order (e.g., second order) the phase profile again:

R_{N}_{ₐ}_{=2,N}_{_{b}}₌₀(x,y)=C₂ exp(2ik₀(\sqrt{x²+y²+f²}−f)) (8)

The reflectivity profile for the first and zeroth diffraction orders can read:

R_{N}_{ₐ}_{=1,N}_{_{b}}₌₀(x,y)=C₁ exp(ik₀(\sqrt{x²+y²+f²}−f)) (9)

R_{N}_{ₐ}_{=0,N}_{_{b}}₌₀(x,y)=C₀ (10)

where C₁ and C₀ are the corresponding coefficients. The implemented profile for the first order can match the profile for a metalens. This can imply that the light scattered in this order can propagate as a collimated beam propagating along the normal to the metasurface based on supercells substrate, since the metalens profile acts as a collimator for the light emitted by the facet. The first order can then be used as the output, and the zeroth order, which can also exist, can be suppressed ensuring C₀=0 with a proper design of the supercell, to avoid unnecessary power losses. The splitting ratio can be accurately controlled in the same way. The tuning mechanism can be unchanged because it can depend on the implemented reflectivity profile for the feedback beam and not on the implementation method. However, the direction of the output beam can be constant upon tuning, because the direction can be normal to the metasurface based on supercells. This effect can enable the implementation of a power-efficient wavelength tunable external cavity laser with a fixed-angle collimated output. Moving the metasurface can create a very small lateral offset in the beam; however, because the beam is collimated, this may not impact the performance of the device, and maintain the alignment of the output beam.

FIG. 7A illustrates a schematic of a wavelength tunable metasurface based external cavity laser in oblique reflection configuration and fixed-angle collimated output. The system can include a gain medium 701. The gain medium 701 can be coated on one side with HR coating and with AR coating on the other side. The gain medium 601 can include one HR coated facet (e.g., facet 702) and an AR coated facet (e.g., facet 703). A low amount of residual light 704 can be transmitted through the HR coating and can be used to monitor the laser power with a detector. The light 705 emerging from the AR coated end of the gain medium can impinge on a metasurface 706 which can focus part of the light directly back to the AR coated laser. Unlike the configuration in FIG. 3, the metasurface can be designed to suppress the specular reflection and the output beam can be generated as a collimated beam (e.g., output beam 707) emerging normally from the metasurface 706. In this case, the cavity can be created between the metasurface and the HR coating, and includes the gain medium. Wavelength tuning can be achieved by changing the position of the metasurface 706 with translation stages 708. However, in this device, the output light can be collimated, and the angle of the output beam may not change upon wavelength tuning. The overlap integral among output beams for different positions of the metasurface can be close to 100%. Wavelength tuning can be achieved via a coarse tuning of the wavelength filtered by the cavity via shifts along the y-axis and a fine control of the cavity overall length via shifts along the x-axis. FIG. 7B illustrates a collimated output beam projected on a screen (e.g., a white screen) based on the device shown in FIG. 7A.

Both the devices shown in FIG. 6 and FIG. 7A have been experimentally validated using a 683 nm diode laser with one inaccessible HR coated facet and one exposed AR coated facet as the gain medium. The reminder of this section will disclose experimental results for the configuration in FIG. 6.

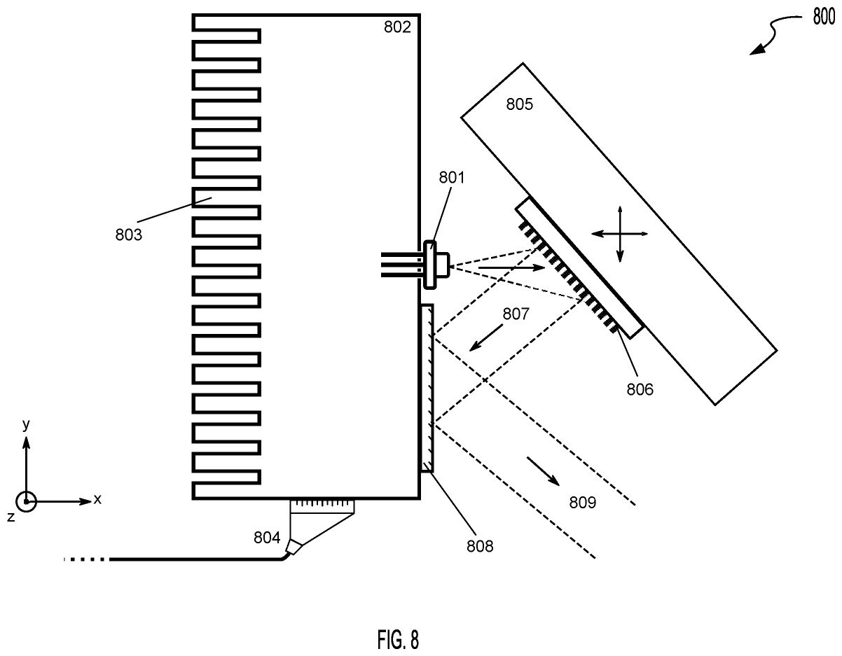

FIG. 8 illustrates a schematic of a wavelength tunable metasurface based external cavity laser in oblique reflection configuration and fixed-angle collimated output including thermoelectric cooling element 802. The system includes a laser diode as a gain medium 801. The laser diode can be mounted on a thermoelectric cooling (TEC) mount. In this example, a laser diode in a TO-can style package is considered. With these packages, only one facet may be accessible and can be AR coated. In some embodiments, a photodiode can be integrated in the package facing the inaccessible HR coated facet. The TEC mount can be large enough to effectively dissipate the heat generated by the diode laser with a heat sink 803 and can include electronics and cables 804 to drive and monitor the laser diode. The metasurface 806 in an oblique reflection configuration and fixed-angle collimated output can be mounted on a translation stage 805 using, for example, a piezoelectric actuator for precise positioning. Due to the geometry of the setup, the collimated output (e.g., output beam 807) of the metasurface can be obstructed by the presence of the TEC element. Placing a mirror 808 on the TEC mount can allow for the reflection of the output beam (e.g., reflected beam) 809 outside of the setup. The output collimated beam can be slightly displaced upon wavelength tuning due to the stage movement, but the displacement can be negligible with respect to the size of the beam. The reflected beam 809 can propagate unobstructed away from the setup.

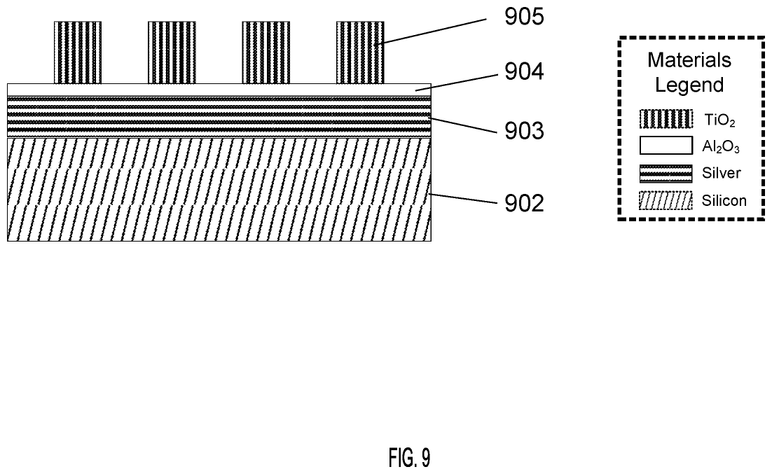

FIG. 9 shows a cross-section of the fabricated metasurface. The metasurface can include a substrate 902. The substrate 902 can be silicon polished along the <111> crystal plane and coated with 1 μm thick layer of silver 907 (e.g., epitaxially grown silver). The layer of silver 903 can be epitaxially deposited with sputtering on a single side polished silicon wafer cut along the <111> crystal axis. The silver can be sufficiently thick to ensure that no light is transmitted through the layer of silver 903. A protection layer 904 (e.g., 10 nm Al₂O₃) can be deposited with atomic layer deposition (ALD) to prevent degradation of silver due to oxygen and sulfur contamination in the atmosphere. The protection layer 904 of 10 nm thick ALD aluminum oxide can be deposited to promote the adhesion of the pillars and to protect the silver layer from atmospheric agents. The metasurface elements can created with patterning methods such as electron beam lithography (EBL) followed by ALD and reactive ion etching (ME) and resist removal. The elements can include pillars (e.g., 300 nm-high pillars). The pillars 905 can be made of TiO₂. The pillars 905 can be created with ALD titanium oxide.

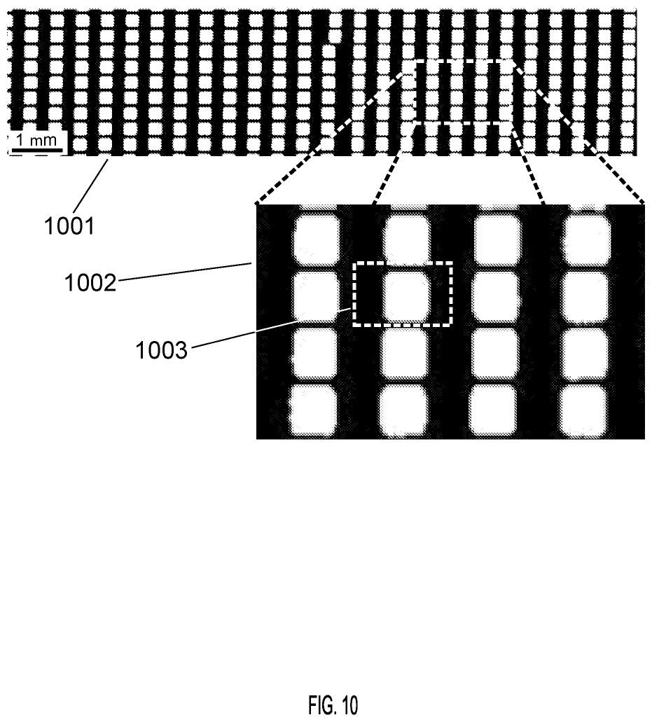

FIG. 10 illustrates a scanning electron microscopy image of a fabricated metasurface 1001 and a detailed panel of the metasurface 1002. The supercell can include a single pillar. Because of the used a(x, y) and b(x, y) functions, the supercells can have the same height, but different width. Therefore, a library including many supercell widths can be optimized, and different widths can be used across the metasurface. The metasurface can be mounted on a translation stage and aligned with the laser with the aid of a microscope. Alignment can be performed by inspecting the laser spot which is retroreflected by the metasurface on the laser facet with the help of the microscope. White rectangles are pillars and the dark background is the silver coated substrate. In this region of the metasurface two distinct supercell types are used, one type on the left and one type on the right. A detailed panel of the metasurface 1002 shows a magnification, where the boundary of a single supercell is shown with a superimposed dashed rectangle 1003.

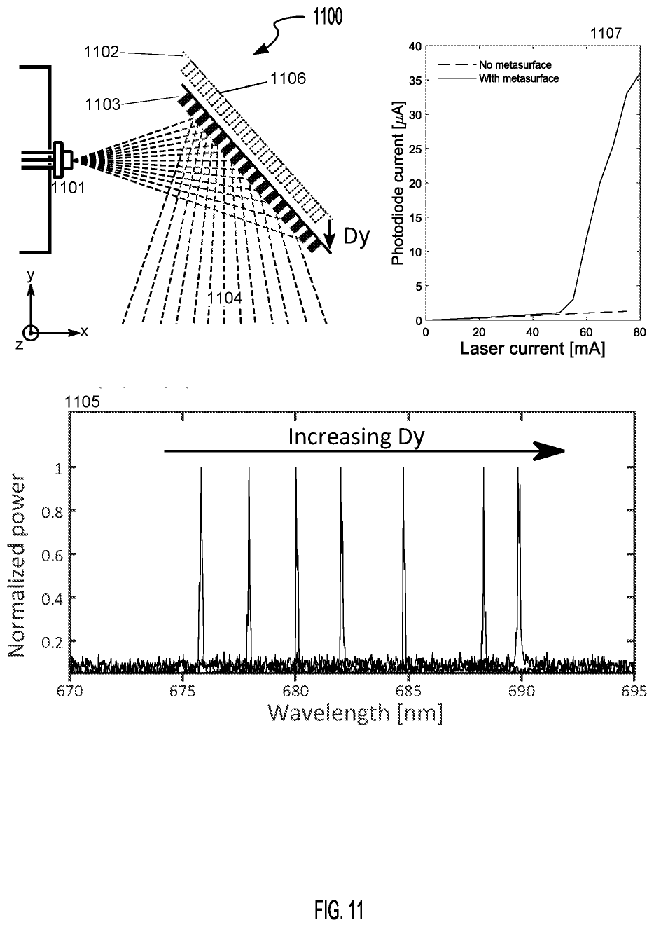

FIG. 11 illustrates a characterization of the fabricated wavelength tunable metasurface 1106. An AR coated laser diode (e.g., gain medium 1101) can be mounted in a TO-can style package. The laser diode can be used as the gain medium 1101. The metasurface 1106 can be in the oblique reflection and divergent output configuration as shown in FIG. 4. As the metasurface 1106 is moved in different positions along the y-axis over a 45 μm range (e.g., from position 1102 to position 1103) the emitted wavelength can be coarsely tuned. The spectrum of the output beam 1104 can be characterized with a spectrometer, and the measurement can indicate a narrow linewidth associated with lasing which can be controlled by displacing the metasurface 1106 in the y-direction 1105. The device can cover all the range of emission of the used laser diode. A spectrometer can be used to verify lasing and to measure the wavelength of the emitted light. In addition, the power can be characterized vs. the current and a clear lasing threshold can be observed. The laser wavelength can be tuned across the entire gain bandwidth of the laser diode. Analog results can be obtained for the configuration with collimated output, which can be achieved using a supercell with two pillars on the same substrate. FIG. 11 shows a plot 1107 of photodiode current (μA) as a function of laser current (mA). Output power can be monitored by integrated photodetector as a function of laser current, with and without metasurface 1106. Lasing can occur with the metasurface 1106. The lasing threshold is visible in the plot 1107 (e.g., between 40 and 60 mA).

A laser device 600, 700, 800, 1100 can include a gain medium 601, 701, 801, 1101 (e.g., active laser medium, lasing medium, etc.). The gain medium 601, 701, 801, 1101 can include a solid-state laser medium. The solid-state laser medium can include a semiconductor laser medium. For example, a semiconductor laser medium can include substrates and/or waveguides used for laser diodes and unipolar lasers. The solid-state laser medium can include a crystal laser medium. The solid-state laser medium can include a doped glass laser medium (e.g., doped optical fibers). The gain medium 601, 701, 801, 1101 can include a gas laser medium. The gain medium 601, 701, 801, 1101 can include dyes for dye lasers. The gain medium 601, 701, 801, 1101 can include a laser medium based on the quantum confinement effect. For example, the laser medium based on the quantum confinement effect can include substrates and waveguides for quantum well lasers, quantum dot lasers, quantum dash lasers, quantum wire lasers, or quantum cascade lasers. The gain medium 601, 701, 801, 1101 can be at least one of a solid-state laser medium, a semiconductor laser medium, a crystal laser medium, a doped glass laser medium, a gas laser medium, a dye, or a quantum confinement effect laser medium. The gain medium 601, 701, 801, 1101 can include a facet 603, 703. The gain medium 601, 701, 801, 1101 can include a laser diode. The facet 603, 703 can include a first facet including an anti-reflective coating. The laser device can include a second facet including a reflective coating. The gain medium 601, 701, 801, 1101 can include a material or system capable of amplifying light. The gain medium 601, 701, 801, 1101 can include a solid state laser medium such as a laser diode waveguide.

The laser device 600, 700, 800, 1100 can include a metasurface 606, 706, 806, 1106. The metasurface 606, 706, 806, 1106 can include a plurality of supercells 502. The plurality of supercells 502 can be arranged in a curvilinear lattice. A curvilinear lattice can include a lattice based on a curvilinear coordinate system in which the coordinate lines are curved. The coordinates can be derived from a set of Cartesian coordinates using a transformation that is locally invertible at each point. Each supercell of the plurality of supercells 502 can include one or more elements 402 (e.g., metasurface elements). The laser device 600, 700, 800, 1100 can occupy a volume of less than a cubic centimeter.

The metasurface 606, 706, 806, 1106 can be disposed on a substrate 401, 505, 902. The metasurface 606, 706, 806, 1106 can be configured to reflect and focus a first portion of light (e.g. light 605, 705) from the facet 603, 703 back to the gain medium 601, 701, 801, 1101 as a feedback beam. An angle and intensity of the feedback beam can be defined according to at least one of a position of the one or more elements, a dimension of the one or more elements, a geometry of the one or more elements, or an orientation of the one or more elements.

The metasurface 606, 706, 806, 1106 can be configured to reflect a second portion of the light as an output beam 607, 707, 807, 1104 at an angle that is nonzero relative to a direction of the feedback beam. An angle and intensity of the output beam 607, 707, 807, 1104 can be defined according to at least one of a position of the one or more elements, a dimension of the one or more elements, a geometry of the one or more elements, or an orientation of the one or more elements. A polarization and shape of the output beam 607, 707, 807, 1104 can be defined according to at least one of a position of the one or more elements, a dimension of the one or more elements, a geometry of the one or more elements, or an orientation of the one or more elements. A phase and shape of the 607, 707, 807, 1104 output beam can be defined according to at least one of a position of the one or more elements, a dimension of the one or more elements, a geometry of the one or more elements, or an orientation of the one or more elements.

The metasurface 606, 706, 806, 1106 can be configured to focus feedback beam at a first point (e.g., I₁) for a first operating wavelength, a second point (e.g., I₂) for a second operating wavelength, and a third point (e.g., I₃) for a third operating wavelength. The first operating wavelength can be different from the second operating wavelength. The first operating wavelength can be different from the third operating wavelength. The second operating wavelength can be different from the third operating wavelength. The first point, the second point, and the third point can be located on a straight line 305.

In some embodiments, spatially translating the metasurface 606, 706, 806, 1106 with respect to the gain medium 601, 701, 801, 1101 modifies a wavelength of the feedback beam (e.g., feedback beam wavelength). For example, spatially translating the metasurface 606, 706, 806, 1106 with respect to the gain medium 601, 701, 801, 1101 modifies the operating laser wavelength. Spatially translating the metasurface 606, 706, 806, 1106 with respect to the gain medium 601, 701, 801, 1101 can leave the angle of the output beam 607, 707, 807, 1104 unchanged. Spatially translating the metasurface 606, 706, 806, 1106 with respect to the gain medium 601, 701, 801, 1101 can include changing a position of the metasurface 606, 706, 806, 1106 while keeping a position of the gain medium 601, 701, 801, 1101 fixed. The position of the metasurface 606, 706, 806, 1106 can be changed to tune the operating wavelength of the laser. The laser device can include one or more translation stages 608, 708 configured to spatially translate the metasurface 606, 706, 806, 1106 with respect to the gain medium 601, 701, 801, 1101. Spatially translating the metasurface 606, 706, 806, 1106 with respect to the gain medium 601, 701, 801, 1101 can modify the wavelength of the feedback beam without changing the angle of the output beam 607, 707, 807, 1104.

The metasurface 606, 706, 806, 1106 can be configured to reflect the output beam 607, 707, 807, 1104 at an angle orthogonal to a plane of the substrate 401, 505, 902. The output beam 707, 807 can be a collimated beam. The collimated beam may not change direction when spatially translating the metasurface 606, 706, 806, 1106 to modify the operating wavelength. A position of the substrate 401, 505, 902 can be changed to tune the operating wavelength of the laser.

In some embodiments, the laser device includes a thermoelectric cooling element 802. The laser device can include a mirror 808 disposed on the thermoelectric cooling element 802 or a substrate of the gain medium (e.g., gain medium substrate). The mirror 808 can be configured to receive the output beam 807 from the metasurface 806 and to reflect the output beam 807 away from the thermoelectric cooling element 802 or the substrate of the gain medium.

In some embodiments, the laser device includes a spatial light modulator (e.g., an electrically reconfigurable element 1506) disposed between the gain medium 601, 701, 801, 1101 and the metasurface 606, 706, 806, 1106. The spatial light modulator can be configured to tune a wavelength of the output beam 607, 707, 807, 1104 (e.g., output beam wavelength). The laser device including a spatial light modulator can achieve wavelength tuning of the output beam 607, 707, 807, 1104 without a need for moving parts. In some embodiments, the spatial light modulator can be integrated directly onto the metasurface. For example, the spatial light modulator can be coupled to the metasurface.

### III. Examples of Wavelength Tunable Metasurface Based External Cavity Lasers in a Transmission Configuration Based on Translation Stages.

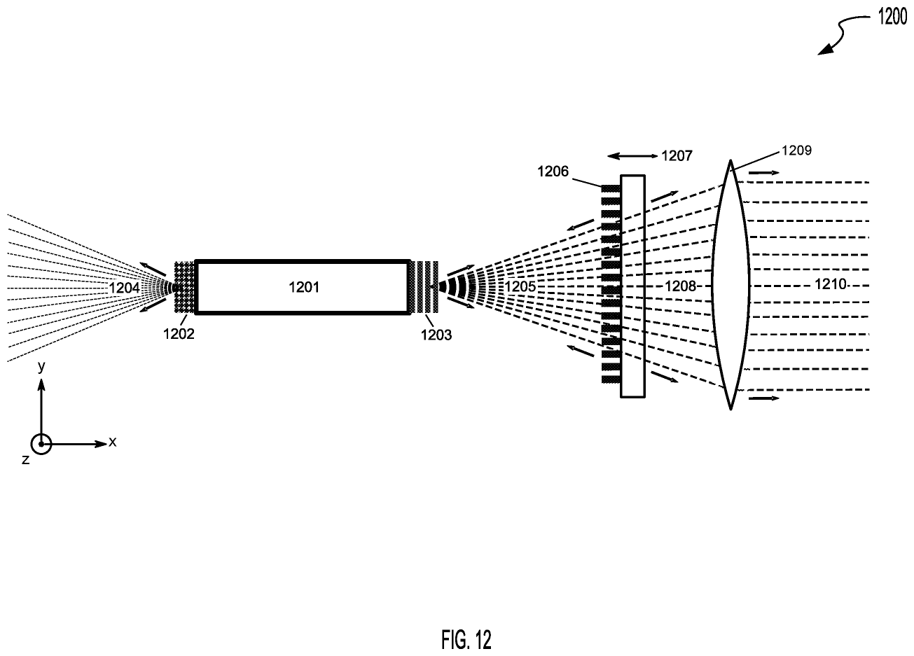

This section discloses examples of wavelength tunable metasurface based external cavity lasers in a transmission configuration based on translation stages. FIG. 12 illustrates a wavelength tunable metasurface based external cavity laser in a normal transmission configuration. The system includes a gain medium 1201. The gain medium 1201 can be coated on one side with an HR coating and with an AR coating on the other side. The gain medium 1201 can include an HR coated facet (e.g., facet 1202) and an AR coated facet (e.g., facet 1203). A low amount of residual light 1204 can be transmitted through the facet 1202 (e.g., HR coating) and can be used to monitor the laser power with a detector. The light 1205 emerging from the AR coated end of the gain medium 1201 can impinge on a metasurface 1206 which can focus part of the light directly back to the AR coated laser as a feedback beam and transmits the rest of the light in the transmitted beam 1208. The cavity can be created between the metasurface 1206 and the HR coating, and includes the gain medium 1201. The output light can be divergent. For this normal metasurface, wavelength tuning can be achieved moving the metasurface 1206 in the x-direction with a translation stage 1207 without changing the orientation of the metasurface 1206. The direction and divergence of the transmitted beam 1208 (e.g., divergent transmitted beam) may not change by this translation. In some embodiments, a lens 1209 or parabolic mirror can be used to collimate the beam to form a collimated beam 1210 (e.g., output collimated beam). The collimated beam 1210 can remain collimated and can propagate in the same direction upon wavelength tuning, regardless of the position of the metasurface 1206.

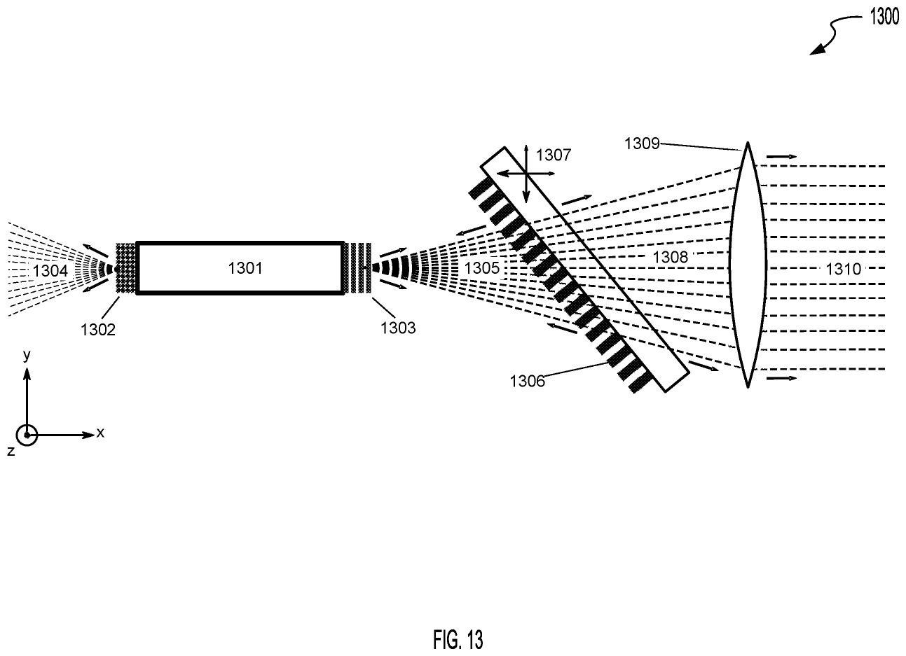

FIG. 13 illustrates a wavelength tunable metasurface based external cavity laser in an off-axis transmission configuration. The system includes a gain medium 1301. The gain medium 1301 is coated on one side with an HR coating and with an AR coating on the other side. The gain medium 1301 can include an HR coated facet (e.g., facet 1302) and an AR coated facet (e.g., facet 1303). A low amount of residual light 1304 is transmitted through the HR coating and can be used to monitor the laser power with a detector. The light 1305 emerging from the AR coated end of the gain medium 1301 can impinge on a metasurface 1306 which focuses part of the light directly back to the AR coated laser as a feedback beam and transmits the rest of the light in the transmitted beam 1308. The cavity is created between the metasurface 1306 and the HR coating, and includes the gain medium 1301. The output light can be divergent. For this off-axis (e.g., oblique) metasurface 1306, coarse wavelength tuning can be achieved by moving the metasurface 1306 in the y-direction with a translation stage 1307 without changing the orientation of the metasurface 1306. The oblique orientation of the metasurface 1306 can be used to achieve a higher selectivity for the coarse selectivity and allow for the fine tuning of the cavity length by moving the metasurface 1306 in the x-direction. The direction and divergence of the transmitted beam 1308 (e.g., divergent transmitted beam) may not change by this translation. Therefore, a lens 1309 or parabolic mirror can be used to collimate the beam to form a collimated beam 1310 (e.g., output collimated beam). The collimated beam 1310 can remain collimated and can propagate in the same direction upon wavelength tuning, regardless of the position of the metasurface 1306.

FIG. 12 and FIG. 13 show examples of embodiments where the metasurface implements, in reflection, the phase profile to provide a feedback to the gain medium, while the metasurface implements a constant phase profile in transmission. A difference with respect to embodiments operating in reflection can be that the output beam is transmitted through the metasurface. The feedback can be created in reflection and with the same principles previously disclosed in this document. Both the normal configuration and the off-axis configurations can be used for these embodiments. In both cases, the transmission configuration can include a transmitted beam 1208, 1308 (e.g., output beam, divergent transmitted beam) that left unchanged by the translation of the metasurface. To obtain a collimated beam 1210, 1310, a lens 1209, 1309 (e.g., auxiliary lens) can be used and the collimated output (e.g., collimated beam 1210, 1310) 1403 can be stable upon wavelength tuning. For these configurations, the metasurface can be moved with translation stages while the laser and the lens can be fixed in place.

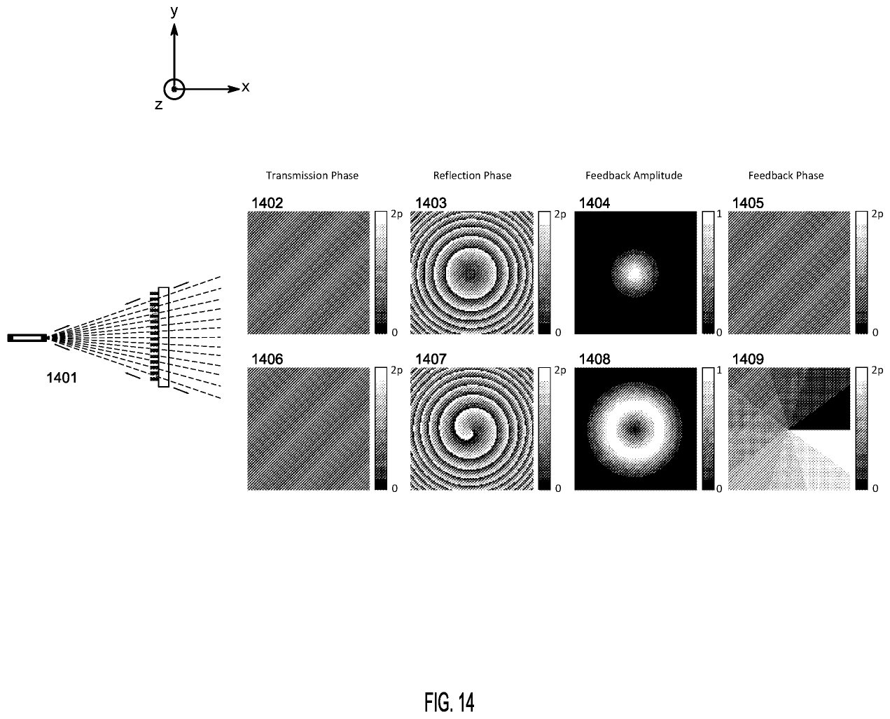

FIG. 14 illustrates an orbital angular momentum singularity in the feedback field. An additional feedback scheme is disclosed here for the case of normal incidence configuration, based on introducing an orbital angular momentum (OAM) singularity in the feedback beam. Two different embodiments are disclosed for the case of metasurfaces in a transmission configuration 1401 illustrated in FIG. 7A. The first metasurface example can implement a uniform transmission phase (panel 1402) and a reflection phase (panel 1403). The first metasurface example may not include an OAM singularity. The uniform transmission phase (panel 1402) and reflection phase (panel 1403) can focus the light back to the gain medium facet (focused feedback). The normalized amplitude and phase of the final feedback on the gain medium for a given wavelength can be plotted as a function of the x, y displacement of the metasurface. The normalized feedback amplitude (panel 1404) can show a maximum obtained when the gain medium facet is placed exactly in the metasurface focus center, while the phase may not show any relevant feature (panel 1405). For the first case (no OAM, panels 1402 to 1405), panels 1402 and 1403 can illustrate the phase profile in transmission and reflection when no OAM singularity is used. The transmission phase can be constant such that that the portion of the light that goes through the metasurface is unchanged. The reflection phase can implement the metamirror functionality described in Equation (2). Calculations can be carried out to compute the complex amplitude (including both amplitude and phase) of the feedback on the facet as a function of the displacement of the metasurface and are illustrated in panels 1404 and 1405. A maximum can be found when the facet is placed in the feedback point, and the amplitude is reduced away from that position. In some embodiments, no relevant variation in phase occurs. These two panels are plotted for x and y displacements with the origin of the plot corresponding to the position for which the facet of the laser is exactly in the feedback point of the metasurface.

The second metasurface example can implement constant phase in transmission (panel 1406) but can have an additional azimuthal phase factor in the reflection phase (panel 1407). The second metasurface example can include an OAM singularity. The normalized feedback amplitude as a function of the x, y displacement of the metasurface (panel 1408) can show a donut-shaped intensity with a phase singularity in the center (panel 1409). The latter configuration can allow for the simultaneous tuning of the feedback coarse filtering (e.g., changing the distance between the metasurface and the facet of the gain medium), the feedback amplitude and phase (e.g., by moving the metasurface laterally, exploring different areas of the donut-shaped feedback). For the second case (with OAM singularity, panels 1406 to 1409) an additional phase factor can b introduced in reflection. Using a polar coordinate system on the metasurface (such that x=r cos θ, y=r sin θ), the additional phase factor can be introduced by multiplying the complex amplitude by exp(ilθ), where i is the imaginary unit and l is an integer number referred to as the topological charge of the OAM singularity. In some embodiments, l=1. The final phase profile for the reflected beam can be:

φ(r,θ)=2k₀(\sqrt{r²+f²}−f)+lθ+φ₀ (11)

The reflection phase can be represented in panel (panel 1407) and takes a spiral geometry. The transmission phase can be left unchanged by choosing the appropriate metasurface elements that satisfy the both phase profiles simultaneously. The feedback amplitude and phase are shown in panels 1408 and 1409. The intensity can be maximum on a ring surrounding a dark region in the center where the singularity is found. The phase can change azimuthally according to the selected value of 1. This can imply that both the intensity and phase of the optical feedback can be selected by displacing the metasurface with respect to the facet of the gain medium in the (x,y) plane. Motion in the z plane can be used to tune the coarse filtering instead. Therefore, this configuration can provide maximum flexibility on all the parameters of the feedback.

A laser device 1200, 1300 can include a gain medium 1201, 1301 (e.g., active laser medium, lasing medium, etc.). The gain medium 1201, 1301 can include a solid-state laser medium. The solid-state laser medium can include a semiconductor laser medium. For example, a semiconductor laser medium can include substrates and/or waveguides used for laser diodes and unipolar lasers. The solid-state laser medium can include a crystal laser medium. The solid-state laser medium can include a doped glass laser medium (e.g., doped optical fibers). The gain medium 1201, 1301 can include a gas laser medium. The gain medium 1201, 1301 can include dyes for dye lasers. The gain medium 1201, 1301 can include a laser medium based on the quantum confinement effect. For example, the laser medium based on the quantum confinement effect can include substrates and waveguides for quantum well lasers, quantum dot lasers, quantum dash lasers, quantum wire lasers, or quantum cascade lasers. The gain medium 1201, 1301 can be at least one of a solid-state laser medium, a semiconductor laser medium, a crystal laser medium, a doped glass laser medium, a gas laser medium, a dye, or a quantum confinement effect laser medium. The gain medium 1201, 1301 can include a facet 1203, 1303. The gain medium 1201, 1301 can include a laser diode. The facet 1203, 1303 can include a first facet including an anti-reflective coating. The laser device can include a second facet including a reflective coating. The gain medium 1201, 1301 can be a material or system capable of amplifying light. The gain medium 1201, 1301 can include a solid state laser medium such as a laser diode waveguide.

The laser device 1200, 1300 can include a metasurface 1206, 1306. The metasurface 1206, 1306 can include a plurality of supercells 502. The plurality of supercells 502 can be arranged in a curvilinear lattice. A curvilinear lattice can include a lattice based on a curvilinear coordinate system in which the coordinate lines are curved. The coordinates can be derived from a set of Cartesian coordinates using a transformation that is locally invertible at each point. Each supercell of the plurality of supercells 502 can include one or more elements 402 (e.g., metasurface elements). The laser device 1200, 1300 can occupy a volume of less than a cubic centimeter.

The metasurface 1206, 1306 can be disposed on a substrate 401, 505, 902. The metasurface 1206, 1306 can be configured to reflect and focus a first portion of light (e.g. light 1205, 1305) from the facet 1203, 1303 back to the gain medium 1201, 1301 as a feedback beam. An angle and intensity of the feedback beam can be defined according to at least one of a position of the one or more elements, a dimension of the one or more elements, a geometry of the one or more elements, or an orientation of the one or more elements.

The metasurface 1206, 1306 can be configured to transmit a second portion of the light as an output beam (e.g., transmitted beam 1208, 1308) through the metasurface 1206, 1306 away from the facet 1203, 1303. An angle and intensity of the transmitted beam 1208, 1308 can be defined according to at least one of a position of the one or more elements, a dimension of the one or more elements, a geometry of the one or more elements, or an orientation of the one or more elements. A polarization and shape of the transmitted beam 1208, 1308 can be defined according to at least one of a position of the one or more elements, a dimension of the one or more elements, a geometry of the one or more elements, or an orientation of the one or more elements. A phase and shape of the transmitted beam 1208, 1308 can be defined according to at least one of a position of the one or more elements, a dimension of the one or more elements, a geometry of the one or more elements, or an orientation of the one or more elements.

The metasurface 1206, 1306 can be configured to focus the feedback beam at a first point (e.g., I₁) for a first operating wavelength, a second point (e.g., I₂) for a second operating wavelength, and a third point (e.g., I₃) for a third operating wavelength. The first operating wavelength can be different from the second operating wavelength. The first operating wavelength can be different from the third operating wavelength. The second operating wavelength can be different from the third operating wavelength. The first point, the second point, and the third point can be located on a straight line 305.

In some embodiments, spatially translating the metasurface 1206, 1306 with respect to the gain medium 1201, 1301 modifies a wavelength of the feedback beam. For example, spatially translating the metasurface 1206, 1306 with respect to the gain medium 1201, 1301 modifies the operating laser wavelength. Spatially translating the metasurface 1206, 1306 with respect to the gain medium 1201, 1301 can include changing a position of the metasurface 1206, 1306 while keeping a position of the gain medium 1201, 1301 fixed. The position of the metasurface 1206, 1306 can be changed to tune the operating wavelength of the laser. The laser device can include a translation stage 1207, 1307 configured to spatially translate the metasurface 1206, 1306 with respect to the gain medium 1201, 1301. Spatially translating the metasurface 1206, 1306 with respect to the gain medium 1201, 1301 can modify the wavelength of the feedback beam without changing a direction of the transmitted beam 1208, 1308.

The laser device can include a lens 1209, 1309 configured to collimate the transmitted beam 1208, 1308 from the metasurface 1206, 1306. The metasurface 1206, 1306 can be configured to provide the output beam as a collimated beam 1210. The metasurface 1206, 1306 can be configured to directly transmit a collimated beam 1210.

In some embodiments, the laser device includes a spatial light modulator (e.g., an electrically reconfigurable element 1506) disposed between the gain medium 1201, 1301 and the metasurface 1206, 1306. The spatial light modulator can be configured to tune a wavelength of the transmitted beam 1208, 1308. The laser device including a spatial light modulator can achieve wavelength tuning of the transmitted beam 1208, 1308 without a need for moving parts.

IV. Examples of Wavelength Tunable Metasurface Based External Cavity Lasers with Electrically Tunable Metasurfaces

This section discloses examples of electrically tunable metasurfaces. In some embodiments, electrically tunable optical materials and/or components can be embedded in the metasurface to implement an electrically tunable phase profile. In some embodiments, electrically tunable metasurfaces can be used for applications such as beam steering, and can be achieved with, for example, liquid crystals, electrically gated 2D materials, electro-optical polymers, electrically gated indium tin oxides, phase change materials, micro-electromechanical systems (MEMS), non-linear materials. In some embodiments, electrically tunable metasurfaces can be based on electrically tuning the emission wavelength of the laser without the use of any mechanical stage. Even with a discrete number of electrical control channels, continuous control of the phase profile can be achieved.

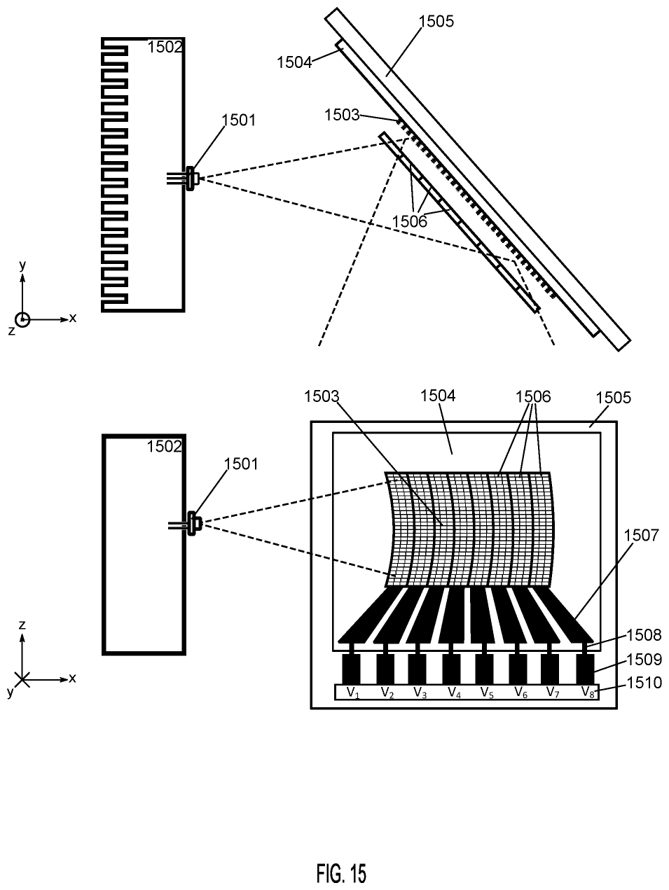

FIG. 15 illustrates an electrically tunable metasurface external cavity laser. The system includes, for example, a laser diode 1501 (e.g., gain medium) mounted on a cooled mount 1502. The metasurface 1503 can be fabricated on a flat substrate 1504 which is mounted on a printed circuit board (PCB) 1505. In some embodiments, there are no moving parts once the system is aligned. In some embodiments, mechanical stages can be used to align the system but are not used to implement wavelength tunability. Wavelength tunability can be achieved using electrical control signals to the metasurface. In some embodiments, electrically tunable material or devices can be embedded in the metasurface 1503, placed above the metasurface 1503, or placed between the metasurface 1503 and the gain medium. The electrically tunable material or devices can include electrically reconfigurable elements 1506 which are connected electrically as a discrete set of elements. Each of the elements 1506 can be tuned electrically. For example, the elements 1506 can include spatial light modulators (SLMs). The SLM can be located at a distance from the metasurface 1503. The SLM can include a micromirror SLM or a liquid crystal SLM. The elements can include tunable pixels. The metasurface can be similar to the experimental demonstrator in FIGS. 5, 6, 9, 10, and 11, and can have additional electrically reconfigurable elements 1506 (e.g., tunable pixels) that can be addressed electrically. These elements 1506 can be larger than the supercell and can be integrated directly on the metasurface or placed between the metasurface and the laser gain medium as a separate device. Each element 1506 can be designed to impart an additional phase factor in the feedback, without affecting the output beam. This design condition can be achieved via numerical optimization of the unit cell. Each tuning element can be connected via metallic interconnects 1507 and wire bonds 1508 to pads 1509 on the PCB. The PCB control circuit can drive the reconfigurable elements with different voltages 1510 so that the additional phase imparted by each element can be controlled individually. This can allow for the electrical control of the feedback pattern and the lasing wavelength.

The total phase profile of the metasurface can include the sum of the phase profile created by the supercell plus the phase profile that can be added using the electrically tunable pixels, which act as a local phase modulation of the optical response. Tunable pixels can have the same size of the metasurface element or have a larger size. The use of a larger size can ease the fabrication, while still allowing for the tuning of the emission wavelength over the full range of the laser. To achieve this, the metasurface can be fabricated to implement a metamirror functionality at the central wavelength A, of the gain medium, when the voltage across all pixels is constant. This can imply that the phase profile is:

φ_{C}(r)=2k_{0C}(\sqrt{r²+f²}−f)+μ_{0C} (12)

with k_{0C}=2π/λ_{c}. The phase profile for a given target wavelength λₜ is:

φₜ(r)=2k₀ₜ(\sqrt{r²+f²}−f)+φ₀ₜ (13)

with k₀ₜ=2π/λₜ. This profile can be achieved using the voltage-controlled pixels to implement the difference of the phase profile, namely:

Δφ(r)=φₜ(r)−φ_{C}(r)=2(k₀ₜ−k_{0C})(\sqrt{r²+f²}−f)+(φ₀ₜ−φ_{0C}) (14)

In such a way, the total implemented phase profile can include the sum of the phase profile implemented by the supercell φ_{C}(r) and the additional phase profile created by the tuneable pixels Δφ(r), which can give φₜ(r), as required to generate the target wavelength.

Because the wavelength range of gain media can be small compared to the central wavelength, the differential phase profile Δφ to be implemented with electrical means can have a small spatial gradient. In some embodiments, the system can be implemented with large voltage-controlled pixels. For example, for a laser diode operating at 700 nm with a tuning range of 10 nm, the pixel size can be up to 70 times larger than the metasurface supercell, while still implementing the differential phase profile with a sufficient approximation. The pixel size can have a size on the order of tens of microns and can be easier to fabricate. Continuous tuning of the wavelength can be achieved by an appropriate modulation of the voltages on each pixel, to control the total phase profile of the electrically tuneable metasurface. FIG. 15 shows how this can be achieved by shaping both the supercell lattice and the tuneable pixels as circular zones, so that the phase has a radial profile and the voltage can be the same across the whole circular zone. In some embodiments, a system using full bi-dimensional spatial light modulation can be fabricated.

### V. Additional Embodiments for Wavelength Tunable Metasurface Based External Cavity Lasers

In some embodiments, the system includes facets which are uncoated, HR coated, or AR coated, or some combination thereof. In some embodiments, the beam emitted by the facet is not coupled to the metasurface and can be used directly as the output beam.

In some embodiments, the metasurface is kept fixed relative to the gain medium and the gain medium is moved with translation stages. In some embodiments, both the metasurface and the gain medium are mounted on translation stages. In some embodiments, the mechanical stage is at least one of manual, motorized, or piezoelectric.

In some embodiments, gain media includes solid-state gain chips or lasers (e.g., quantum cascade lasers, laser diode, quantum well lasers, quantum dot lasers, fiber lasers, gas lasers, dye lasers, or metal vapor lasers). In some embodiments, the laser can emit light or radiation in the visible spectrum. In some embodiments, the laser can emit light or radiation in the near-infrared or mid-infrared spectrum.

In some embodiments, the metasurface based on supercells is used to engineer the radiation pattern and/or the polarization of the output beam. In some embodiments, the metasurface based on supercells is used to shape the output and feedback beams with arbitrary patterns and polarization patterns.

In some embodiments, the gain medium supports multiple polarizations and the metasurface can be used to select the polarization of the lasing mode in the cavity. This can be achieved by designing a feedback beam with different patterns according to the polarization of the incident light, and the polarization can be selected by shifting the relative position of the metasurface and the laser. For different positions, the maximum roundtrip gain can be achieved for a different polarization, which can determine the polarization of the lasing mode. Similar to the aforementioned OAM singularity, this functionality can be introduced by adding a polarization singularity in the feedback beam.

In some embodiments, feedback is created for more than one wavelength at the same time. For example, this can be achieved by interleaving two separate metasurfaces (e.g., creating a metasurface with alternating elements taken from two separate metasurface designs, obtaining a metasurface which can perform both functions at the same time). This approach can be generalized to the metasurfaces based on supercells disclosed herein. Creating a feedback on two separate wavelengths can induce multimode lasing in several gain media, such as QCLs, quantum dot lasers (QDLs) and laser diodes. Inducing multiple wavelength lasing in the same medium can be exploited to achieve difference frequency generation (DFG), within the gain medium, a mechanism that can be used to generate coherent light at longer wavelengths (including the terahertz range) or radiofrequency signals via photo-mixing or similar non-linear phenomena.

In some embodiments, feedback occurs on multiple wavelengths with an engineered phase relation used for passive mode locking the lasing signal in the time domain. This includes engineering the phase and amplitude envelope of frequency combs (e.g., in time or frequency domain) generated in the laser system when more than one wavelength can lase, and the wavelengths can be synchronized via mode-locking. Time domain control of optical pulses can be achieved using simple schemes in metasurfaces.

In some embodiments, non-linear materials or saturable absorbers are embedded in the metasurface or as an auxiliary optical component to implement mode-locking schemes. In some embodiments, electrically tunable metasurfaces include radiofrequency signals that are used to drive the metasurface elements to implement active mode-locking schemes.

In some embodiments, the beam emitted by the gain medium is astigmatic and the metasurface design allows for the correction of the astigmatism. This astigmatic beam emitted by the facets can diverge from different points for different cross sections. Therefore, the beam may not be focused to a diffraction limited spot with a normal lens. Many laser diode designs can show strong astigmatism and may not suitable for external cavity lasers. However, the metasurface based on supercells approach disclosed here can allow for the shaping of the feedback beam and the compensation of astigmatism. Therefore, this approach can be compatible even with astigmatic laser diode or other astigmatic gain chips or media. The gain medium can be an astigmatic solid-state laser and the metasurface can compensate astigmatism to increase the output power.

In some embodiments, the metasurface is used to select the transversal mode in the gain medium. For example, for high power laser diodes, the waveguide is larger to create more power, resulting in the possibility of having more than one mode propagating along it. With an appropriate design of the output beam, it is possible to selectively create feedback for one mode while suppressing the others.

In some embodiments, the metasurface is coupled to more than one gain medium. For example, one of the gain media can be used to amplify the signal generated by the other one which is part of the main cavity. In another example, more gain media can work in parallel and the metasurface can be used to combine each beam to obtain a high-power output beam. In some embodiments, each gain medium can provide gain at different overlapping wavelength ranges, and the system can provide seamless continuous wavelength tuning across the union of the wavelength ranges.

In some embodiments, the output beam is engineered to focus light on a fiber facet so that the final system outputs light via an optical fiber. In some embodiments, the metasurface can serve as a coupler to an additional high finesse optical cavity, which can be replaced and changed without affecting the alignment of the metasurface.

In some embodiments, one or more auxiliary metasurfaces are used together with the main metasurface forming the cavity as explained above. The auxiliary metasurfaces can be mounted on translation stages and have the following functionalities: (1) implement additional beam forming/shaping and polarization optics in transmission on either the feedback beam or the output beam, (2) implement a discontinuity inside the external cavity to achieve higher selectivity for the wavelength selection via the Vernier effect. The implemented coarse filter may not be sufficient to select one single wavelength. An etalon can increase the fine tuning of the cavity and suppress unwanted mode hopping.

In some embodiments, a partially reflective mirror is placed after the collimated output to achieve an effectively longer cavity split in two parts, which also shows the Vernier effect and can therefore achieve better control on the fine-tuning mechanism. In some embodiments, auxiliary lenses and curved mirrors are used to shape the output beam.

In some embodiments, nanoscale elements are composed of a semiconductor, an oxide (e.g., a metal or non-metal oxide), a nitride (e.g., a metal or non-metal nitride), a sulfide (e.g., a metal or non-metal sulfide), a pure element, or a combination of two or more of these. In some embodiments, nanoscale elements may include a dielectric material. Examples of suitable dielectric materials include metal and non-metal oxides (such as an oxide of aluminum (e.g., Al₂O₃), silicon (e.g., SiO₂), hafnium (e.g., HfO₂), zinc (e.g., ZnO), magnesium (e.g., MgO), or titanium (e.g., TiO₂)), metal and non-metal nitrides (such as nitrides of silicon (e.g., Si₃N₄), boron (e.g., BN), or tungsten (e.g., WN)), metal and non-metal sulfides, and pure elements (e.g., silicon for operation at near-infrared and mid-infrared wavelengths).

In some embodiments, the first plurality of nanoscale elements may include nanopillars (e.g., pillar-like, three-dimensional structures or volumes). In some embodiments, nanoscale elements are slanted nanopillars with a nonzero slant angle with respect to a surface normal of a metasurface grating. In some embodiments, the nonzero slanted angle is about 1 degree or greater, about 2 degrees or greater, about 5 degrees or greater, or about 10 degrees or greater.

In some embodiments, the optical device may include a transmissive substrate including glass or polymer. The first plurality of nanoscale elements and/or the second plurality of nanoscale elements may be disposed on the transmissive substrate. In some embodiments, a substrate is transparent in the visible spectrum, such as a polymer substrate, a glass substrate or one including fused silica. Suitable substrates that are transparent in the visible spectrum can have a light transmittance of at least about 40%, at least about 50%, at least about 60%, at least about 70%, at least about 80%, at least about 85%, at least about 90%, or at least about 95%, over the visible spectrum or a design or working wavelength in the visible spectrum.

Embodiments of the subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatus. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices).

The operations described in this specification can be performed by a data processing apparatus on data stored on one or more computer-readable storage devices or received from other sources. The term “data processing apparatus” or “computing device” encompasses various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a circuit, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more circuits, subprograms, or portions of code). A computer program can be deployed to be executed on one computer or on multiple computers that are located at one site or distributed across multiple sites and interconnected by a communication network.

Processors suitable for the execution of a computer program include, by way of example, microprocessors, and any one or more processors of a digital computer. A processor can receive instructions and data from a read only memory or a random access memory or both. The elements of a computer are a processor for performing actions in accordance with instructions and one or more memory devices for storing instructions and data. A computer can include, or be operatively coupled to receive data from or transfer data to, or both, one or more mass storage devices for storing data, e.g., magnetic, magneto optical disks, or optical disks. A computer need not have such devices. Moreover, a computer can be embedded in another device, e.g., a personal digital assistant (PDA), a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, implementations of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

The implementations described herein can be implemented in any of numerous ways including, for example, using hardware, software or a combination thereof. When implemented in software, the software code can be executed on any suitable processor or collection of processors, whether provided in a single computer or distributed among multiple computers.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

A computer employed to implement at least a portion of the functionality described herein may comprise a memory, one or more processing units (also referred to herein simply as “processors”), one or more communication interfaces, one or more display units, and one or more user input devices. The memory may comprise any computer-readable media, and may store computer instructions (also referred to herein as “processor-executable instructions”) for implementing the various functionalities described herein. The processing unit(s) may be used to execute the instructions. The communication interface(s) may be coupled to a wired or wireless network, bus, or other communication means and may therefore allow the computer to transmit communications to or receive communications from other devices. The display unit(s) may be provided, for example, to allow a user to view various information in connection with execution of the instructions. The user input device(s) may be provided, for example, to allow the user to make manual adjustments, make selections, enter data or various other information, or interact in any of a variety of manners with the processor during execution of the instructions.

The various methods or processes outlined herein may be coded as software that is executable on one or more processors that employ any one of a variety of operating systems or platforms. Additionally, such software may be written using any of a number of suitable programming languages or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the solution discussed above. The computer readable medium or media can be transportable, such that the program or programs stored thereon can be loaded onto one or more different computers or other processors to implement various aspects of the present solution as discussed above.

The terms “program” or “software” are used herein to refer to any type of computer code or set of computer-executable instructions that can be employed to program a computer or other processor to implement various aspects of embodiments as discussed above. One or more computer programs that when executed perform methods of the present solution need not reside on a single computer or processor, but may be distributed in a modular fashion amongst a number of different computers or processors to implement various aspects of the present solution.

Computer-executable instructions may be in many forms, such as program modules, executed by one or more computers or other devices. Program modules can include routines, programs, objects, components, data structures, or other components that perform particular tasks or implement particular abstract data types. The functionality of the program modules can be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

As used herein, the singular terms “a,” “an,” and “the” may include plural referents unless the context clearly dictates otherwise.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

Any references to implementations or elements or acts of the systems and methods herein referred to in the singular can include implementations including a plurality of these elements, and any references in plural to any implementation or element or act herein can include implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementations,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Elements other than ‘A’ and ‘B’ can also be included.

The systems and methods described herein may be embodied in other specific forms without departing from the characteristics thereof. The foregoing implementations are illustrative rather than limiting of the described systems and methods.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

The systems and methods described herein may be embodied in other specific forms without departing from the characteristics thereof. The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1.-20. (canceled)

21. An optical device comprising:
a metasurface comprising a plurality of supercells, the metasurface disposed on a substrate and are configured to reflect or transmit a portion of light as an output beam,
wherein the plurality of supercells are groupings of sub-wavelength optical elements which exert arbitrary phase and/or amplitude control over a set of diffraction orders,
wherein each supercell of the plurality of supercells includes a lateral dimension which is greater than a wavelength, and
wherein the plurality of supercells include two or more different supercells at different positions to exert different phase and/or amplitude control at the different positions.

22. The optical device of claim 21, wherein
the metasurface is configured to reflect the output beam at an angle orthogonal to a plane of the substrate; and
the output beam is a collimated beam.

23. The optical device of claim 21, wherein the plurality of supercells is arranged in a curvilinear lattice.

24. The optical device of claim 21, wherein the metasurface is configured to:
reflect and focus a first portion of light as a feedback beam; and
reflect a second portion of the light as the output beam at an angle that is nonzero relative to a direction of the feedback beam.

25. The optical device of claim 24, wherein:
each supercell of the plurality of supercells comprise one or more elements; and
an angle and intensity of the feedback beam and an angle and intensity of the output beam are defined according to at least one of a position of the one or more elements, a dimension of the one or more elements, a geometry of the one or more elements, or an orientation of the one or more elements.

26. The optical device of claim 21, wherein a polarization and shape of the output beam are defined according to at least one of a position of the sub-wavelength optical elements, a dimension of the sub-wavelength optical elements, a geometry of the sub-wavelength optical elements, or an orientation of the sub-wavelength optical elements.

27. The optical device of claim 21, wherein the metasurface is configured to focus a feedback beam at a first point for a first operating wavelength, a second point for a second operating wavelength, and a third point for a third operating wavelength; wherein the first point, the second point, and the third point are located on a straight line.

28. The optical device of claim 21, wherein a phase and shape of the output beam are defined according to at least one of a position of the sub-wavelength optical elements, a dimension of the sub-wavelength optical elements, a geometry of the sub-wavelength optical elements, or an orientation of the sub-wavelength optical elements.

29. The optical device of claim 21, wherein the metasurface is further configured to reflect and focus a first portion of light as a feedback beam.

30. The optical device of claim 29, wherein the output beam is reflected at an angle that is nonzero relative to a direction of the feedback beam.

31. The optical device of claim 29, wherein the output beam is transmitted through the metasurface.

32. The optical device of claim 21, wherein the supercells provide a complex amplitude profile in reflection for a reflection or diffraction order defined by:
R_{N}_{ₐ}_{,N}_{_{b}}(x,y)=|C_{N}_{ₐ}_{,N}_{_{b}}(nₐ,n_{b}))exp(2πiNₐa(x,y)+2πiN_{b}b(x,y))
where the coordinate system is defined by two continuous functions a(x,y) and b(x,y) defined in such a way that lattice points correspond to values of x and y such that a and b are integer numbers, where the supercells are indexed with integers (nₐ,n_{b}) such that nₐ=a(x,y) and n_{b}=b(x,y), and where Nₐ, N_{b} are the indexes of the reflection or diffraction order, nₐ and n_{b} are the indexes of the supercell found at position (x,y), and |C_{N}_{ₐ}_{,N}_{_{b}}(nₐ,n_{b})) is the reflection coefficient of the supercell for the reflection or diffraction order.

33. The optical device of claim 32, wherein a feedback beam is first order and the output beam is zeroth order.

34. The optical device of claim 33, wherein the first order is defined by:
R_{N}_{ₐ}_{=0,N}_{_{b}}₌₀(x,y)=C₀, and
wherein the zeroth order is defined by:
R_{N}_{ₐ}_{=1,N}_{_{b}}₌₀(x,y)=C₁ exp(2ik₀(\sqrt{x²+y²+f²}−f))

35. The optical device of claim 21, wherein the supercells are arranged such that all the supercells have the same size along the y-axis and are distributed in regular rows.

36. The optical device of claim 35, wherein the supercells are further arranged such that the supercells have variable position and size along the x-axis to implement a phase profile.

37. The optical device of claim 21, further comprising a gain medium comprising a facet, wherein the metasurface is further configured to reflect and focus a first portion of light from the facet back to the gain medium as a feedback beam and reflect a second portion of light as the output beam.

38. The optical device of claim 37, wherein spatially translating the metasurface with respect to the gain medium modifies a wavelength of the feedback beam.

39. The optical device of claim 21, wherein the plurality of supercells include two or more different supercells at different lattice positions.

40. The optical device of claim 21, further comprising:
a gain medium; and
a spatial light modulator disposed between the gain medium and the metasurface, the gain spatial light modulator configured to tune a wavelength of the output beam.
